(19) United States
(12) Patent Application Publication
(10) Pub. No.: US 2010/0233426 A1
(43) Pub. Date: Sep. 16, 2010

(54) NOBLE METAL SINGLE CRYSTALLINE NANOWIRE AND THE FABRICATION METHOD THEREOF

(75) Inventors: Bongsoo Kim, Daejeon (KR); Yeongdong Yoo, Daejeon (KR)

Correspondence Address: CANTOR COLBURN, LLP, 20 Church Street, 22nd Floor, Hartford, CT, 06103, US

(73) Assignee: KOREA ADVANCED INSTITUTE OF SCIENCE AND TECHNOLOGY, Daejeon (KR)

(21) Appl. No.: 12/667,118

(22) PCT Filed: Jun. 27, 2008
(86) PCT No.: PCT/KR2008/003737

§ 371 Date: Feb. 1, 2010

(30) Foreign Application Priority Data
Jun. 29, 2007 (KR) 10-2007-0064993
Jun. 29, 2007 (KR) 10-2007-0065030
Apr. 18, 2008 (KR) 10-2008-0036360

(51) Int. Cl. B32B 7/00; C30B 25/10; C30B 25/18; B32B 15/04; H01L 21/20; H01L 29/66; B82B 3/00; B82B 1/00

(52) U.S. Cl. 428/119; 117/88; 117/102; 428/457; 428/292.1; 438/478; 257/9; 977/762; 257/E21.09; 257/E29.168

(57) ABSTRACT

The present invention provides a method for fabricating a single crystalline noble metal nanowire using noble metal oxide, noble metal material or noble metal halide as a precursor and a single crystalline noble metal nanowire, and more particularly a method for fabricating a single crystalline noble metal nanowire on a single crystalline substrate by heat treating a precursor located at a front portion of a furnace and a substrate located at a rear portion of the furnace in an inert flow atmosphere and a single crystalline noble metal nanowire fabricated by the fabrication method. The present invention fabricates a single crystalline noble metal nanowire by non-catalytic vapor phase transport method, the process is simple and reproducible, the fabricated nanowire is a defect free and impurity free, high quality and high purity noble metal nanowire of complete single crystal state.

### TECHNICAL FIELD

The present invention relates to a method for fabricating noble metal nanowire by a vapor phase transport method using noble metal oxide, noble metal material or noble metal halide as a precursor and a noble metal nanowire fabricated by the same method.

### BACKGROUND ART

In general, single crystalline noble metal nanowire can be utilized in electric, magnetic and optical devices and sensors because of its high chemical stability, high thermal conductivity, and high electric conductivity.

Particularly, Ag has excellent electric and thermal conductivities and shows highest surface enhanced Raman scattering (SERS) in the visible region due to its optical property. When fabricating Ag into the form of a nanowire, wide application and development in microelectronic devices and optical sensors can be expected. Particularly, in case of SERS, since magnitude of a signal depends largely on detailed shape of Ag nanostructure, a technology of fabricating a well defined and well analyzed nanowire having clear surface is most important in fabrication of reliable chemical or bio sensors.

Similarly to Ag, the SERS phenomenon can be observed in case of Au. In general, in case of metal nanostructures, it is possible to adsorb molecules onto the surface of the metal nanostructure using a self-assembled monolayer (SAM). With this phenomenon, it is possible to obtain a molecular layer uniformly adsorbed onto the surface of the Au nanostructural body. Observation of SERS phenomenon of molecules using the Au nanowire and the SAM and application of the molecules forming the SAM as a linker will permit large utilization as a selective biomolecular analysis and optical devices. Also, use of the Au nanowire structure in the SERS measurement is expected to be a high sensitive analysis technology.

Pd is getting attention due to its utilization as a sensor. Development of variety of accurate gas sensors still remained as a great challenge in the fields requiring high accuracy with development of science and technology. Also, the sensors with excellent sensibility have not yet been developed around the world. Particularly, development of a high sensitive hydrogen gas sensor for a fuel cell, which can monitor leakage of hydrogen generable upon commercialization of the fuel cell, still remained as a challenge to be studied together with the fuel cell to be used as the next generation clean energy. Also, development of the material to be used in the sensor is considered as important as the development of the hydrogen gas sensor. One of those mostly getting attention is metal Pd and there have been made worldwide studies on synthesis of a nanowire using the metal Pd, which has strong absorption ability of the hydrogen and can absorb the hydrogen having a volume of 900 times greater than its own volume, and application thereof as a high sensitive sensor.

As described above, the noble metal nanowire can be very utilized as electric, magnetic or optical devices or sensors. However, there has been reported no case in which the noble metal nanowire had been synthesized in vapor phase. Conventionally known method for synthesizing the noble metal nanowire includes mainly a liquid phase chemical method using a template, a surfactant and a capping agent and there has not yet been reported up to now a case in which the noble metal nanowire had been successfully fabricated using the vapor phase without catalyst.

However, the liquid phase chemical method has disadvantages that it is difficult to control the shape of the noble metal nanowire, and the fabricated noble metal nanowire has lowered purity and is defective or multi-crystalline.

Also, the fabrication method is more complex than the vapor phase synthetic method and thus is difficult to apply to mass production.

Above all, the technical proposition of enhancement in device performance according to reduction in device size suggests needs for basic studies with respect to synthesis and properties of the nanowire. This nanowire is generally fabricated by what is known as bottom-up type synthetic method and the nanowire is grown in disordered position and direction due to the characteristic of the synthetic method. Since this disorderly grown nanowire functions as an obstruction factor that obstructs an actual application of the nanowire, a process capable of accurately controlling the position and direction of the nanowire should be preceded to realize a large size device.

The present inventor suggest a method for fabricating a mass producible noble metal nanowire with high purity and high quality and, as an advanced form, a method capable of controlling the position and direction of the nanowire through accurate control for the growth of the noble metal nanowire, thereby providing a base for realizing a three-dimensional device through the noble metal nanowire with controlled orientation for arrangement with respect to a substrate

Further, it has been known that when vertically grown noble metal nanowire is doped with trace amount of transition metal such as Co, Fe, Mn, the noble metal nanowire shows ferromagnetic property. Therefore, the synthetic method by vertical growth of the present invention will provide a basic technology that is very important in fabrication of a three-dimensional memory.

### DISCLOSURE

### Technical Problem

An object of the present invention is to provide a high purity and high quality single crystalline noble metal nanowire having an orientation with a substrate using non-catalytic vapor phase transport method and a method for fabricating the same, and another object of the present invention is to provide a device or sensor provided with the single crystalline noble metal nanowire of the present invention.

### Technical Solution

Hereinafter, a method for fabricating a single crystalline noble metal nanowire using vapor phase transport method under non-catalyst condition will be described in detail.

The method for fabricating a single crystalline noble metal nanowire is characterized in that a precursor containing noble metal oxide, noble metal material or noble metal halide located at a front portion of a furnace and a semiconductive or nonconductive single crystalline substrate located at a rear portion of the reactor furnace are heat treated in an inert gas flow atmosphere, thereby forming a single crystalline noble metal nanowire on the single crystalline substrate.

The method of the present invention is a method of forming the noble metal nanowire on a single crystalline substrate not using the catalyst but simply using noble metal oxide, noble metal material or noble metal halide as the precursor, and has advantages that the process is simple and reproducible, and high purity nanowire containing no impurities can be fabricated since the noble metal nanowire is fabricated through a vapor phase mass transfer path without using the catalyst.

Also, since driving force for nucleation, driving force for growth, nucleation rate and growth rate of the metal material is finally controlled on the upper portion of the single crystalline substrate by controlling independently a temperature of the front portion of the furnace and a temperature of the rear portion of the furnace and controlling the flow rate of the inert gas and the pressure in the heat treating furnace tube used in the heat treatment, it is possible to fabricate high quality single crystalline noble metal nanowire with no defect and good crystallinity which is reproducible and controllable of size and density on the substrate of the single crystalline noble metal nanowire.

Therefore, the subject matter of the present invention is to fabricate metal nanowire by the vapor phase transport method not using catalyst but using noble metal oxide, noble metal material or noble metal halide as a precursor, and the most important condition for fabricating the nanowire with high quality, high purity and desirable shape is temperatures at the front and rear portions of furnace, flow rate of the inert gas and pressure upon the heat treatment.

The precursor usable in the fabrication of the noble metal nanowire may include noble metal oxide, noble metal material and metal halide. The noble metal oxide is preferably selected from silver oxide, gold oxide and palladium oxide; the noble metal material is preferably selected from silver, gold and palladium; and the noble metal halide is preferably selected from noble metal fluoride, noble metal chloride, noble metal bromide and noble metal iodide, more preferably selected from noble metal chloride, noble metal bromide and noble metal iodide and most preferably noble metal iodide. The noble metal halide is preferably selected from gold halide, silver halide and palladium halide. The gold halide is preferably selected from gold fluoride, gold chloride, gold bromide and gold iodide; the silver halide is preferably selected from silver fluoride, silver chloride, silver bromide and silver iodide; and the palladium halide is preferably selected from palladium fluoride, palladium chloride, palladium bromide and palladium iodide. Also, the noble metal halide may include noble metal halide hydrate.

The precursor is preferably noble metal oxide or noble metal material and more preferably noble metal oxide.

To control magnetic property of the noble metal nanowire, the precursor may further include transition metal material. Examples of the transition metal material may include Co, Fe, Mg, Mn, Cr, Zr, Cu, Zn, V, Ti, Nb and Y, and a mixture thereof.

The temperatures and pressure upon the heat treatment and the flow rate of the inert gas may be changed independently of each other, but it is possible to obtain single crystalline noble metal nanowire with desirable quality and shape only when the three conditions are changed dependently of other conditions.

Therefore, the most preferable single crystalline noble metal nanowire may be fabricated from combination of above three conditions.

The respective temperatures of the front portion of the furnace and the rear portion of the furnace should be determined according to physical properties such as melting point, evaporation point and evaporation energy of the precursor, the flow rate of the inert gas and pressure upon the heat treatment, but it is preferred that the temperature of the front portion of furnace is maintained equal or higher than the temperature of the rear portion of the furnace, and the temperature difference by subtracting the temperature of the rear portion of the furnace from the temperature of the front portion of the furnace is 0 to 700° C.

The inert gas is flowed preferably in 100 to 600 sccm from the front portion of the furnace to the rear portion of the furnace. When the precursor is noble metal oxide or noble metal material, the inert gas is flowed preferably in 400 to 600 sccm and more preferably in 450 to 550 sccm from the front portion of the furnace to the rear portion of furnace. When the precursor is noble metal halide, the inert gas is flowed preferably in 100 to 300 sccm from the front portion of the furnace to the rear portion of furnace.

The pressure upon the heat treatment is preferably lower than atmospheric pressure, more preferably 2 to 50 torr and most preferably 2 to 20 torr. However, when the precursor is noble metal halide, the noble metal nanowire may be fabricated at a pressure similar to the atmospheric pressure.

The temperature of the furnace, the flow rate of the inert gas and the pressure upon the heat treatment have influences on evaporation degree of the precursor, amount per hour of the evaporated precursor transported to the substrate, nucleation and growth rate of the ferromagnetic metal material on the substrate and surface energy, agglomeration degree and morphology of noble metal material (nanowire) produced on the substrate.

Therefore, under the condition of the aforementioned temperature, flow rate of the inert gas and pressure upon the heat treatment, it is possible to fabricate the noble metal nanowire with the most desirable quality and shape by vapor phase transport method using the precursor of the present invention. When the condition goes out of the aforementioned range, there may occur a quality problem such as agglomeration, shape deformation and defect of the fabricated nanowire and a problem of obtaining a metal body having a shape of not the nanowire but particles or a rod.

Heat treatment time should be also determined according to the aforementioned temperature, flow rate of the inert gas and pressure upon the heat treatment and is carried out preferably for 30 minutes to 2 hour. During the heat treatment time, the precursor evaporated by the inert gas is moved to the substrate to participate in nucleation and growth, and at the same time, mass transfer (mass transfer on a per atom or cluster basis) through vapor phase and substrate surface occurs between already formed noble metal materials, and Ostwald ripening occurs.

Therefore, it is possible to control density and size of the noble metal nanowire by heat treating again the substrate formed with the noble metal nanowire with the precursor being removed after the aforementioned heat treatment.

As described above, the present invention suggests use of noble metal oxide, noble metal material or noble metal halide as a precursor and a vapor phase transport method capable of fabricating noble metal nanowire using the precursor. Therefore, the precursor usable in the fabrication method of the present invention includes all noble metal oxide, noble metal material and noble metal halide, and all noble metal single crystalline nanowire can be fabricated using the precursor. Particularly, examples of the noble metal oxide may include gold oxide, silver oxide, palladium oxide, platinum oxide, iridium oxide, osmium oxide, rhodium oxide and ruthenium oxide, and using the noble metal oxide, gold, silver, palladium, platinum, iridium, osmium, rhodium or ruthenium single crystalline nanowire can be fabricated.

The noble metal oxide of gold oxide, silver oxide, palladium oxide, platinum oxide, iridium oxide, osmium oxide, rhodium oxide and ruthenium oxide may be an oxide having a stoichiometric ratio that is thermodynamically stable at atmospheric temperature and pressure, or may be a noble metal oxide not having the stable stoichiometric ratio, which is resulted from point defects due to the noble metal or point defects due to oxygen.

All semiconductive or nonconductive single crystalline substrates that are chemically/thermally stable in the aforementioned heat treatment condition can be used as the substrate, but it is preferred a single crystalline substrate selected from group 4 single crystal selected from silicon single crystal, germanium single crystal and silicon-germanium single crystal, groups 3-5 single crystal selected from gallium-arsenic single crystal, indium-phosphorus single crystal and gallium-phosphorus single crystal, groups 2-6 single crystal, groups 4-6 single crystal, sapphire single crystal and silicon dioxide single crystal.

However, since the substrate acts simply to provide a space for forming the noble metal nanowire on the upper portion thereof, a multi-crystal of aforementioned single crystalline substrate material may be used if necessary.

As described above, since the respective temperatures of the front portion of the furnace and the rear portion of the furnace should be determined according to physical properties such as melting point, evaporation point and evaporation energy of the noble metal oxide and noble metal material, when fabricating Ag single crystalline nanowire using silver oxide as the noble metal oxide, silver or silver halide, it is preferred that the temperature difference by subtracting the temperature of the rear portion of the furnace from the temperature of the front portion of the furnace is 250 to 650° C., the precursor (noble metal oxide) is maintained at 850 to 1050° C. and the single crystalline substrate is maintained at 400 to 600° C.

When fabricating Au single crystalline nanowire using gold oxide as the noble metal oxide, gold or gold halide, it is preferred that the temperature difference by subtracting the temperature of the rear portion of the furnace from the temperature of the front portion of the furnace is 0 to 300° C., the precursor is maintained at 1000 to 1200° C. and the single crystalline substrate is maintained at 900 to 1000° C.

When fabricating Pd single crystalline nanowire using palladium oxide as the noble metal oxide, palladium or palladium halide, it is preferred that the temperature difference by subtracting the temperature of the rear portion of the furnace from the temperature of the front portion of the furnace is 0 to 300° C., the precursor is maintained at 1000 to 1200° C. and the single crystalline substrate is maintained at 900 to 1000° C.

Hereinafter, a method for fabricating a single crystalline noble metal nanowire having a predetermined orientation with the single crystalline substrate in accordance with the present invention will be described.

The single crystalline noble metal nanowire is characterized in that it is fabricated under a non-catalytic condition using the precursor containing noble metal oxide, noble metal material or noble metal halide and thus has an orientation with the surface of the semiconductive or nonconductive single crystalline substrate.

The orientation means the direction of the major axis of the nanowire fabricated on the substrate with respect to the surface of the substrate, and the nanowire has characteristically vertical or horizontal orientation with the surface of the substrate.

The noble metal single crystalline nanowire is fabricated by heat treating the precursor located at the front portion of the furnace and the single crystalline substrate located at the rear portion of the furnace in an inert gas flow atmosphere with a predetermined pressure, and the orientation is controlled by kinds of the precursor, kinds of the single crystalline substrate, surface direction of the single crystalline substrate, the heat treatment temperature, the flow rate of the inert gas, the pressure or combination thereof.

The noble metal nanowire having a specific orientation with the substrate is preferably fabricated in such a condition that the precursor is maintained at 1000 to 1200° C., the single crystalline substrate is maintained at 800 to 1100° C., the inert gas is flowed in 50 to 200 sccm from the front portion of the furnace (precursor) to the rear portion of the furnace (single crystalline substrate) and the heat treatment is carried out at a pressure of 3 to 20 torr.

At this time, the precursor usable in the fabrication of the noble metal nanowire may include noble metal oxide, noble metal material and metal halide, and the noble metal single crystalline nanowire can be fabricated using them. Examples of the noble metal oxide may include gold oxide, silver oxide, palladium oxide, platinum oxide, iridium oxide, osmium oxide, rhodium oxide and ruthenium oxide, and gold, silver, palladium, platinum, iridium, osmium, rhodium or ruthenium single crystalline nanowire can be fabricated using the noble metal oxide. Examples of the noble metal material may include gold, silver, palladium, platinum, iridium, osmium, rhodium and ruthenium. The noble metal halide is preferably selected from noble metal fluoride, noble metal chloride, noble metal bromide and noble metal iodide, more preferably selected from noble metal chloride, noble metal bromide and noble metal iodide and most preferably noble metal chloride. The noble metal of the noble metal halide is selected gold, silver, palladium, platinum, iridium, osmium, rhodium and ruthenium, and the noble metal halide includes noble metal halide hydrate.

The precursor is preferably noble metal oxide or noble metal material.

It is preferred that the noble metal oxide is selected from gold oxide and palladium oxide, the noble metal material is selected from gold and palladium, and the noble metal halide is selected from gold halide and palladium halide.

The noble metal single crystalline nanowire has the same crystalline structure as noble metal bulk and has high purity and high crystallinity. Also, a plurality of the noble metal single crystalline nanowires is arranged in a specific array.

The single crystalline noble metal nanowire is grown vertically with respect to the surface of the single crystalline substrate and thus has a vertical orientation.

The noble metal single crystalline nanowire having the vertical orientation has the same crystalline structure as noble metal bulk and a faceted shape. At this time, the faceted shape means that the surface is not constituted of all plane in the crystal and an inclination of a tangent line is discontinuously varied on a periphery of a specific section including the minor axis or major axis of the noble metal nanowire.

The vertically grown single crystalline noble metal nanowire is Au single crystalline nanowire and the Au single crystalline nanowire has a face centered cubic (FCC) structure. Also, the Au single crystalline nanowire has a faceted shape, and the inclination of the tangent line is discontinuously varied on the periphery of the major axis section of the Au single crystalline nanowire. The growth direction is <110> and thus the Au single crystalline nanowire has an orientation in which the surface of the substrate and <110> direction of the Au single crystalline nanowire are perpendicular to each other. Preferably, {0001} surface of a sapphire single crystalline substrate and the <110> direction of the Au single crystalline nanowire are perpendicular to each other.

The vertically grown single crystalline noble metal nanowire is Pd single crystalline nanowire and the Pd single crystalline nanowire has a face centered cubic (FCC) structure. Also, the Pd single crystalline nanowire has a faceted shape, and the inclination of the tangent line is discontinuously varied on the periphery of the major axis section of the Pd single crystalline nanowire. The growth direction is <110> and thus the Pd single crystalline nanowire has an orientation in which the surface of the substrate and <110> direction of the Pd single crystalline nanowire are perpendicular to each other. Preferably, {0001} surface of a sapphire single crystalline substrate and the <110> direction of the Pd single crystalline nanowire are perpendicular to each other

The noble metal nanowire having a vertical orientation with the substrate is preferably fabricated in such a condition that the precursor is maintained at 1000 to 1200° C., the single crystalline substrate is maintained at 850 to 1100° C., the inert gas is flowed in 50 to 200 sccm from the front portion of the furnace to the rear portion of the furnace at a pressure of 3 to 8 torr.

The noble metal single crystalline nanowire is grown horizontally parallel to the surface of the single crystalline substrate and thus has a horizontal orientation.

The single crystalline noble metal nanowire which is grown horizontally parallel to the surface of the substrate is Au single crystalline nanowire. The Au single crystalline nanowire has a face centered cubic (FCC) structure and the surface of the substrate and {110} or {111} face of the Au nanowire are parallel to each other.

The single crystalline substrate is preferably a {0001} surface sapphire substrate and has an orientation in which the {0001} face of the substrate and the {110} face of the Au nanowire are parallel to each other.

The single crystalline substrate is preferably a {11-20} surface sapphire substrate and has an orientation in which the {11-20} face of the substrate and the {111} face of the Au nanowire are parallel to each other.

The single crystalline noble metal nanowire which is grown horizontally parallel to the surface of the substrate is Pd single crystalline nanowire, and the Pd single crystalline nanowire has a face centered cubic (FCC) structure. At this time, the single crystalline substrate on which the Pd single crystalline nanowire is fabricated is preferably a {0001} surface sapphire substrate.

The noble metal nanowire having a horizontal orientation with the substrate is preferably fabricated in such a condition that the precursor is maintained at 1000 to 1200° C., the single crystalline substrate is maintained at 800 to 950° C., the inert gas is flowed in 50 to 200 sccm from the front portion of the furnace to the rear portion of the furnace at a pressure of 15 to 20 torr.

The single crystalline substrate is group 4 single crystalline substrate; groups 3-5 single crystalline substrate; groups 2-6 single crystalline substrate; groups 4-6 single crystalline substrate; sapphire single crystalline substrate; silicon oxide single crystalline substrate; or a stacked substrate thereof, and preferably a sapphire single crystalline substrate.

The method for fabricating a single crystalline noble metal nanowire is characterized in that the single crystalline noble metal nanowire an orientation with the single crystalline substrate is fabricated by heat treating a precursor containing noble metal oxide, noble metal material or noble metal halide located at the front of the furnace and a semiconductive or nonconductive single crystalline substrate located at the rear portion of the furnace in an inert gas flow atmosphere at a predetermined pressure.

The orientation means the direction of the major axis of the nanowire fabricated on the substrate with respect to the surface of the substrate, and the major axis of the single crystalline noble metal nanowire has characteristically vertical or horizontal orientation with the surface of the substrate.

In the fabrication method in accordance with the present invention, the orientation is controlled by kinds of the precursor, kinds of the single crystalline substrate, surface direction of the single crystalline substrate, the heat treatment temperature, the flow rate of the inert gas, the pressure or combination thereof.

At this time, the precursor usable in the fabrication of the noble metal nanowire may include noble metal oxide, noble metal material and metal halide, and the noble metal single crystalline nanowire can be fabricated using them. Examples of the noble metal oxide may include gold oxide, silver oxide, palladium oxide, platinum oxide, iridium oxide, osmium oxide, rhodium oxide and ruthenium oxide, and gold, silver, palladium, platinum, iridium, osmium, rhodium or ruthenium single crystalline nanowire can be fabricated using the noble metal oxide. Examples of the noble metal material may include gold, silver, palladium, platinum, iridium, osmium, rhodium and ruthenium. The noble metal halide is preferably selected from noble metal fluoride, noble metal chloride, noble metal bromide and noble metal iodide, more preferably selected from noble metal chloride, noble metal bromide and noble metal iodide and most preferably noble metal chloride. The noble metal of the noble metal halide is selected gold, silver, palladium, platinum, iridium, osmium, rhodium and ruthenium, and the noble metal halide includes noble metal halide hydrate.

The precursor is preferably noble metal oxide or noble metal material.

It is preferred that the noble metal oxide is selected from gold oxide and palladium oxide, the noble metal material is selected from gold and palladium, and the noble metal halide is selected from gold halide and palladium halide.

The single crystalline substrate is group 4 single crystalline substrate; groups 3-5 single crystalline substrate; groups 2-6 single crystalline substrate; groups 4-6 single crystalline substrate; sapphire single crystalline substrate; silicon oxide single crystalline substrate; or a stacked substrate thereof, and preferably a sapphire single crystalline substrate.

In the fabrication method in accordance with the present invention, the single crystalline noble metal nanowire is grown vertically with respect to the surface of the single crystalline substrate. At this time, it is preferred that the precursor is maintained at 1000 to 1200° C., the single crystalline substrate is maintained at 850 to 1100° C., the inert gas flows in 50 to 200 sccm from the front portion of the furnace to the rear portion of the furnace, and the heat treatment is carried out at a pressure of 3 to 8 torr. The single crystalline substrate on which the vertically growing single crystalline noble metal nanowire is fabricated is preferably a {0001} surface sapphire substrate.

The precursor is gold oxide or gold and the vertically growing single crystalline noble metal nanowire is Au single crystalline nanowire.

The precursor is palladium oxide or palladium and the vertically growing single crystalline noble metal nanowire is Pd single crystalline nanowire.

In the fabrication method in accordance with the present invention, the single crystalline noble metal nanowire is grown horizontally parallel to the surface of the single crystalline substrate. At this time, it is preferred that the precursor is maintained at 1000 to 1200° C., the single crystalline substrate is maintained at 800 to 950° C., the inert gas flows in 50 to 200 sccm from the front portion of the furnace to the rear portion of the furnace, and the heat treatment is carried out at a pressure of 15 to 20 torr.

The single crystalline substrate on which the horizontally growing single crystalline noble metal nanowire is fabricated is preferably a sapphire substrate, and the surface of the sapphire substrate is {0001} face or {11-20} face.

The precursor is gold oxide or gold and the horizontally growing single crystalline noble metal nanowire is Au single crystalline nanowire.

The precursor is palladium oxide or palladium and the horizontally growing single crystalline noble metal nanowire is Pd single crystalline nanowire.

Hereinafter, the method for fabricating a noble metal nanowire having an orientation with the single crystalline substrate in accordance with the present invention will be described in detail.

The method for fabricating the single crystalline noble metal nanowire having an orientation with the substrate is characterized in that a precursor containing noble metal oxide, noble metal material or noble metal halide located at a front portion of a furnace and a semiconductive or nonconductive single crystalline substrate are heat treated in an inert gas flow atmosphere at a predetermined pressure, thereby forming a single crystalline noble metal nanowire having an orientation on the single crystalline substrate.

Specifically, the precursor evaporated by the heat treatment is transferred by the flow of the inert gas to cause nucleation and growth of the noble metal on the surface of the single crystalline substrate, thereby forming the single crystalline noble metal nanowire having vertical or horizontal orientation with the surface of the single crystalline substrate.

The fabrication method of the present invention is a method of forming the noble metal nanowire on the single crystalline substrate not using catalyst but simply using the noble metal oxide, noble metal material or noble metal halide as a precursor, and has advantages that the process is simple and reproducible and high purity nanowire containing no impurities can be fabricated since the noble single crystalline metal nanowire is fabricated through a vapor phase mass transfer path without using catalyst.

Also, fabrication method of the present invention has advantages that it is possible to fabricate the single crystalline noble metal nanowire having vertical or horizontal orientation with the surface of the substrate, being independent from each other without agglomeration and arranged uniformly in a specific direction, by controlling the nucleation and growth.

The major axis of the single crystalline noble metal nanowire produced by nucleation and growth on the substrate has vertical or horizontal relationship with respect to the surface of the single crystalline substrate, and this vertical or horizontal orientation is controlled by kinds of the precursor, kinds of the single crystalline substrate, surface direction of the single crystalline substrate, the heat treatment temperature, the flow rate of the inert gas, the pressure or combination thereof.

Specifically, by controlling respectively temperatures of the front portion and rear portion of the furnace, controlling surface phase and surface energy of targeting noble metal single crystal through control of the flow rate of the inert gas and the pressure in a heat treatment tube used upon the heat treatment, and finally controlling nucleation driving force, growth driving force, nucleation rate and growth rate of the noble metal material on the upper portion of the single crystalline substrate, the noble metal nanowire having a specific orientation with the single crystalline substrate by nucleation and growth of the noble metal material.

At this time, the substrate is the surface of nonconductive or semiconductive single crystal on which nucleation, particularly two dimensional nucleation of the targeting noble metal single crystal is easily generated, and should be suitably selected so that elastic stress and dislocation due to lattice mismatch are not easily generated.

Two dimensional nucleation energy barrier of the noble metal single crystal is determined by material of targeting single crystal noble metal nanowire, atomic structure of low index faces of the targeting single crystal noble metal nanowire, material of the single crystalline substrate, surface direction of the single crystalline substrate or a combination thereof.

In addition, when the material of targeting single crystal noble metal nanowire is identical, the nucleation and growth are varied as material of the single crystalline substrate, surface direction of the single crystalline substrate or a combination thereof and the orientation of the single crystalline noble metal nanowire with respect to the substrate may be finally controlled.

As described above, all semiconductors and nonconductors that allow easy nucleation of the targeting single crystalline noble metal nanowire and are chemically/thermally stable in the aforementioned heat treatment condition can be used as the semiconductive or nonconductive substrate, but the semiconductive or nonconductive substrate is actually selected from group 3 single crystal selected from silicon single crystal, germanium single crystal and silicon-germanium single crystal, groups 3-5 single crystal selected from gallium-arsenic single crystal, indium-phosphorus single crystal and gallium-phosphorus single crystal, groups 2-6 single crystal, groups 4-6 single crystal, sapphire single crystal and silicon dioxide single crystal, or a stacked substrate thereof.

For example, when the targeting single crystalline noble metal nanowire is Au or Pd single crystalline nanowire, a low cost sapphire single crystal is actually used, in which the nucleation of the noble metal is easily generated on the low index surface which is a thermodynamically stable surface.

As described above, in order to fabricate the noble metal nanowire having an orientation with the surface of the single crystalline substrate, it is necessary to control initial nucleation and growth step of the noble metal material. The most important conditions for controlling the step are the pressure in the heat treatment tube, the heat treatment temperatures of the front portion of the furnace (precursor) and the rear portion of the furnace (substrate) and flow rate of the inert gas.

Through theoretical and experimental results, it is known that all materials having crystallinity are subject to phase transformation, which results in change of atomic structure (singular-rough) of the surface due to temperature, pressure, atmosphere, impurities, etc. having influence on surface energy. Temperature has the largest influence on the phase transformation, and the shape thermally stable at high temperature is a spherical shape having no facet. At this time, the atoms on the surface have atomically rough structure. At low temperature, an influence of broken bond energy according to crystal direction of the single crystal becomes larger than entropy energy and thus the single crystal comes to have a faceted shape. Each face constituting the faceted shape is the surface in the crystal direction of low surface energy and the surface is known to have atomically singular structure.

This thermodynamic phase transformation has large influence of the nucleation and growth of the particle. Normal nucleation and growth occur when the atomic structure is a rough structure, but two dimensional nucleation and lateral growth occur when the atomic structure is a singular structure.

In the method for fabricating the noble metal nanowire arranged so as to have a specific orientation with the surface of the single crystalline substrate, the arranged orientation is obtained by controlling the thermally stable surface phase of the noble metal material using the heat treatment temperature and pressure, and controlling nucleation and growth driving forces transferred to the substrate surface through the control of the flow rate of the inert gas.

To meet the aforementioned nucleation and growth condition, it is preferred that the precursor is maintained at 1000 to 1200° C., the single crystalline substrate is maintained at 800 to 1100° C., the inert gas flows in 50 to 200 sccm from the front portion of the furnace (precursor) to the rear portion of the furnace (single crystalline substrate), and the heat treatment is carried at a pressure of 3 to 30 torr.

When the condition goes out of the aforementioned desirable temperature, pressure and flow rate of the inert gas, the orientation with the surface of the single crystalline substrate may be lost, a noble metal having a shape of not the nanowire but particles or a rod can be obtained, or a nanowire constituted of not single crystal but multi-crystal may be produced.

To fabricate the noble metal nanowire arranged so as to have a vertical orientation with the surface of the single crystalline substrate, it is preferred that the precursor is maintained at 1000 to 1200° C., the single crystalline substrate is maintained at 850 to 1100° C., the inert gas flows in 50 to 200 sccm from the front portion of the furnace (precursor) to the rear portion of the furnace (single crystalline substrate), and the heat treatment is carried at a pressure of 3 to 8 torr.

To fabricate the noble metal nanowire arranged so as to have a horizontal orientation with the surface of the single crystalline substrate, it is preferred that the precursor is maintained at 1000 to 1200° C., the single crystalline substrate is maintained at 800 to 950° C., the inert gas flows in 50 to 200 sccm from the front portion of the furnace (precursor) to the rear portion of the furnace (single crystalline substrate), and the heat treatment is carried at a pressure of 15 to 20 torr.

Heat treatment time should be also determined according to the aforementioned temperature, flow rate of the inert gas and pressure upon the heat treatment and is carried out preferably for 30 minutes to 2 hour. During the heat treatment time, the precursor evaporated by the inert gas is moved to the substrate to participate in nucleation and growth, and at the same time, mass transfer of the noble metal material through vapor phase and substrate surface occurs between already formed noble metal materials, and particle growth occurs.

Therefore, it is possible to control density and size of the noble metal nanowire arranged so as to have an orientation with the single crystalline substrate by heat treating again the single crystalline substrate formed with the noble metal nanowire with the precursor being removed after the aforementioned heat treatment.

The precursor usable in the fabrication of the noble metal nanowire may include noble metal oxide, noble metal material and metal halide, and the noble metal single crystalline nanowire can be fabricated using them. Examples of the noble metal oxide may include gold oxide, silver oxide, palladium oxide, platinum oxide, iridium oxide, osmium oxide, rhodium oxide and ruthenium oxide, and gold, silver, palladium, platinum, iridium, osmium, rhodium or ruthenium single crystalline nanowire can be fabricated using the noble metal oxide. Examples of the noble metal material may include gold, silver, palladium, platinum, iridium, osmium, rhodium and ruthenium, and gold, silver, palladium, platinum, iridium, osmium, rhodium or ruthenium single crystalline nanowire can be fabricated using the noble metal material. The noble metal halide is preferably selected from noble metal fluoride, noble metal chloride, noble metal bromide and noble metal iodide, more preferably selected from noble metal chloride, noble metal bromide and noble metal iodide and most preferably noble metal chloride. The noble metal of the noble metal halide is selected gold, silver, palladium, platinum, iridium, osmium, rhodium and ruthenium, and the noble metal halide includes noble metal halide hydrate.

The precursor is preferably noble metal oxide or noble metal material.

To control magnetic property of the noble metal nanowire, the precursor may further include transition metal material. Examples of the transition metal material may include Co, Fe, Mg, Mn, Cr, Zr, Cu, Zn, V, Ti, Nb and Y, and a mixture thereof.

Using gold oxide, gold or gold halide, preferably gold oxide or gold as the precursor, it is possible to fabricate an arranged Au single crystalline nanowire having an orientation with the surface of the single crystalline substrate. Also, using palladium oxide, palladium or palladium halide, preferably palladium oxide or palladium as the precursor, it is possible to fabricate an arranged Pd single crystalline nanowire having an orientation with the surface of the single crystalline substrate.

At this time, the gold halide is preferably selected from gold fluoride, gold chloride, gold bromide and gold iodide, and the palladium halide is preferably selected from palladium fluoride, palladium chloride, palladium bromide and palladium iodide.

### DESCRIPTION OF DRAWINGS

The above and other objects, features and advantages of the present invention will become apparent from the following description of preferred embodiments given in conjunction with the accompanying drawings, in which:

FIG. 1 is a scanning electron microscope (SEM) image showing an Ag nanowire fabricated through Example 1 of the present invention.

FIG. 2 is a transmission electron microscope (TEM) image showing the Ag nanowire fabricated through Example 1 of the present invention.

FIG. 3 shows electronic diffraction patterns according to zone axes of the Ag nanowire fabricated through Example 1 of the present invention.

FIG. 4 is a high resolution TEM (HRTEM) image showing the Ag nanowire fabricated through Example 1 of the present invention.

FIG. 5 is an energy dispersive spectroscopy (EDS) result of the Ag nanowire fabricated through Example 1 of the present invention.

FIG. 6 is an X-ray diffraction (XRD) result of the Ag nanowire fabricated through Example 1 of the present invention.

FIG. 7 is a SEM image showing an Au nanowire fabricated through Example 2 of the present invention.

FIG. 8 is an XRD result of the Au nanowire fabricated through Example 2 of the present invention.

FIG. 9 is a TEM result of the Ag nanowire fabricated through Example 1 of the present invention, in which FIG. 9a is a selected area electron diffraction pattern (SAED) of the Ag nanowire in FIG. 9b and FIG. 9b is a dark field image of the Ag nanowire.

FIG. 10 is an EDS result of the Au nanowire fabricated through Example 2 of the present invention.

FIG. 11 is a SEM image showing a Pd nanowire fabricated through Example 3 of the present invention.

FIG. 12 is an XRD result of the Pd nanowire fabricated through Example 3 of the present invention.

FIG. 13 is a TEM result of the Pd nanowire fabricated through Example 3 of the present invention, in which FIG. 13a is a SAED of the Pd nanowire in FIG. 13b and FIG. 13b is a dark field image of the Pd nanowire.

FIG. 14 is an EDS result of the Pd nanowire fabricated through Example 3 of the present invention.

FIG. 15 is a SEM image showing a Pd nanowire fabricated through Example 4 of the present invention.

FIG. 16 is a TEM result of the Pd nanowire fabricated through Example 4 of the present invention, in which an image inserted in upper right portion of FIG. 16 is a SAED of the Pd nanowire in FIG. 16.

FIG. 17 is an EDS result of the Pd nanowire fabricated through Example 4 of the present invention.

FIG. 18 is a SEM image showing an Au nanowire fabricated through Example 5 of the present invention.

FIG. 19 is a high magnification SEM image showing the Au nanowire fabricated through Example 5 of the present invention.

FIG. 20 is a SEM image showing an Au nanowire fabricated through Example 6 of the present invention.

FIG. 21 is an XRD result of the Au nanowire fabricated through Example 6 of the present invention.

FIG. 22 is a TEM result of the Au nanowire fabricated through Example 6 of the present invention, in which FIG. 22a is a SAED of the Au nanowire in FIG. 22b, FIG. 22b is a dark field image of the Au nanowire and FIG. 22c is a HRTEM of FIG. 22b.

FIG. 23 is an EDS result of the Au nanowire fabricated through Example 6 of the present invention.

FIG. 24 is a SEM image showing a Pd nanowire fabricated through Example 7 of the present invention.

FIG. 25 is an XRD result of the Pd nanowire fabricated through Example 7 of the present invention.

FIG. 26 is a TEM result of the Pd nanowire fabricated through Example 7 of the present invention, in which FIG. 26a is a SAED of the Pd nanowire in FIG. 26b, FIG. 26b is a dark field image of the Pd nanowire and FIG. 26c is a HRTEM of FIG. 26b.

FIG. 27 is an EDS result of the Pd nanowire fabricated through Example 7 of the present invention.

FIG. 28 is a SEM image showing an Au nanowire fabricated through Example 8 of the present invention.

FIG. 29 is a HRTEM image showing an interface between the Au nanowire fabricated through Example 8 of the present invention and a substrate.

FIG. 30 is a SEM image showing an Au nanowire fabricated through Example 9 of the present invention.

FIG. 31 is a HRTEM image showing an interface between the Au nanowire fabricated through Example 9 of the present invention and a substrate.

FIG. 32 is a SEM image showing a Pd nanowire fabricated through Example 10 of the present invention.

### BEST MODE

Hereinafter, methods for fabricating a single crystalline noble metal nanowire by vapor phase transport method under a non-catalytic condition will be described in detail through Examples 1 to 5.

### Example 1

An Ag single crystalline nanowire was synthesized in a furnace using vapor phase transport method.

The furnace is divided into a front portion and a rear portion, which are independently provided with a heating element and a temperature controller. A tube in the furnace was formed of quartz having a size of 1 inch diameter and 60 cm length.

In a middle of the front portion of the furnace was located a boat-shaped receptacle of high purity alumina material containing 0.5 g of Ag₂O (Sigma-Aldrich, 226831) as a precursor and in a middle of the rear portion of the furnace was located a silicon substrate. Argon gas is inputted into the front portion of the furnace and discharged from the rear portion of the furnace, and the rear portion of the furnace is provided with a vacuum pump. A pressure within the quartz tube was maintained at 15 torr using the vacuum pump and Ar was allowed to flow in 500 sccm by using a mass flow controller (MFC).

As the silicon substrate, a silicon wafer having (100) crystal face formed with a natural oxidation layer on the surface thereof was used.

Heat treatment was carried out for 30 minutes in a state that the temperature of the front portion of the furnace (alumina boat containing the precursor) is maintained at 950° C. and the temperature of the rear portion of the furnace (substrate) is maintained at 500° C., thereby fabricating Ag single crystalline nanowire.

### Example 2

An Au single crystalline nanowire was synthesized in a furnace using vapor phase transport method.

The Au single crystalline nanowire was fabricated using the same condition and apparatus of Example 1, except for the precursor, the heat treatment temperature and the material of the single crystalline substrate.

0.05 g of Au₂O₃ (Sigma-Aldrich, 3304057) was used as the precursor and a (0001) surface sapphire single crystal was used as the single crystalline substrate.

Heat treatment was carried out for 30 minutes in a state that the temperature of the front portion of the furnace (alumina boat containing the precursor) is maintained at 1100° C. and the temperature of the rear portion of the furnace (sapphire substrate) is maintained at 900° C., thereby fabricating Au single crystalline nanowire.

### Example 3

A Pd single crystalline nanowire was synthesized in a furnace using vapor phase transport method.

The Pd single crystalline nanowire was fabricated using the same condition and apparatus of Example 1, except for the precursor, the heat treatment temperature, the pressure and the material of the single crystalline substrate.

0.03 g of PdO (Sigma-Aldrich, 203971) was used as the precursor, and a (0001) surface sapphire single crystal was used as the single crystalline substrate. The pressure in the quartz tube was maintained at 5 torr using the vacuum pump.

Heat treatment was carried out for 30 minutes in a state that the temperature of the front portion of the furnace (alumina boat containing the precursor) is maintained at 1100° C. and the temperature of the rear portion of the furnace (sapphire substrate) is maintained at 900° C., thereby fabricating Pd single crystalline nanowire.

According to the method of the present invention, a Pd single crystalline nanowire was fabricated using palladium as the precursor (Example 4), and an Au single crystalline nanowire was fabricated using gold chloride as the precursor (Example 5)

### Example 4

A Pd single crystalline nanowire was synthesized in a furnace using vapor phase transport method.

The Pd single crystalline nanowire was fabricated using the same condition and apparatus of Example 3, except that 0.03 g of Pd (Sigma-Aldrich, 203939) was used as the precursor.

### Example 5

An Au single crystalline nanowire was synthesized in a furnace using vapor phase transport method.

The Au single crystalline nanowire was fabricated using the same condition and apparatus of Example 2, except for the precursor, the pressure and the flow rate of the inert gas.

0.05 g of AuCl (Sigma-Aldrich, 481130) was used as the precursor, the pressure in the quartz tube was maintained at 5 torr using the vacuum pump, and Ar was allowed to flow in 150 sccm by using the MFC.

By analyzing the single crystalline noble metal nanowires fabricated through Examples 1 to 5, quality, shape and purity of the single crystalline noble metal nanowires fabricated by the fabrication method of the present invention were analyzed.

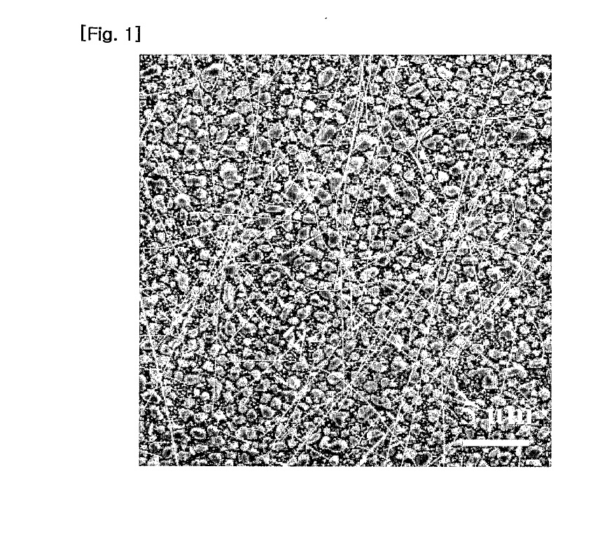

FIGS. 1 to 6 show results of measuring the Ag nanowire fabricated through Example 1.

FIG. 1 is a scanning electron microscope (SEM) image showing the Ag nanowire fabricated through Example 1 of the present invention. As can be appreciated from FIG. 1, a large amount of nanowires was formed in uniform size of tens micrometer separably from the silicon single crystalline substrate, Ag nanowire having a shape extending straightly in a major axis direction of the nanowire and individually separable without agglomeration of the nanowires were formed, and a diameter of minor axis of the Ag single crystalline nanowire is 80 to 150 nm and a length of the major axis thereof is greater than 10 μm.

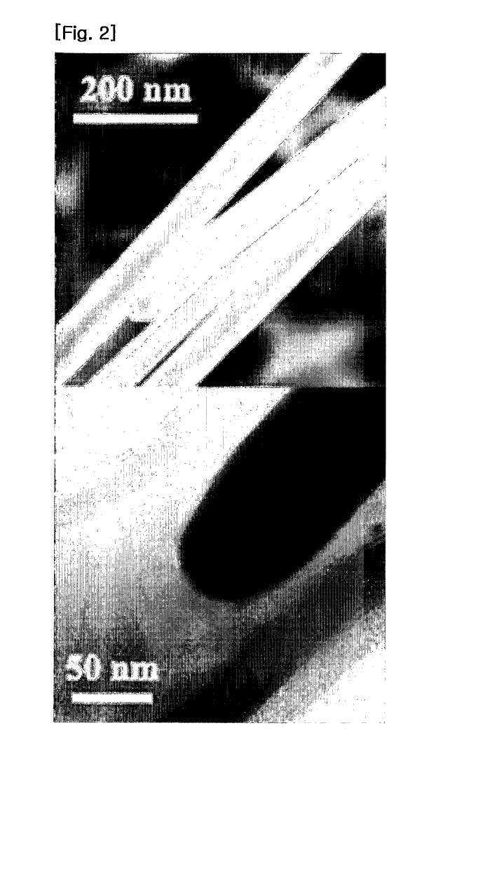

FIG. 2 is a transmission electron microscope (TEM) image showing the Ag nanowire. When observing the shape of the fabricated Ag nanowire through FIG. 2, it can be appreciated that the Ag nanowire having smooth surface was formed, the section of the Ag single crystalline nanowire perpendicular to the growth direction has smoothly curved shape in which an inclination of the tangent line on the periphery of the section is continuously varied and the section has a circular shape for minimizing the surface energy. Also, it can be appreciated that a section of a growth directional end of the Ag single crystalline nanowire has an elliptic shape with no faceted portion.

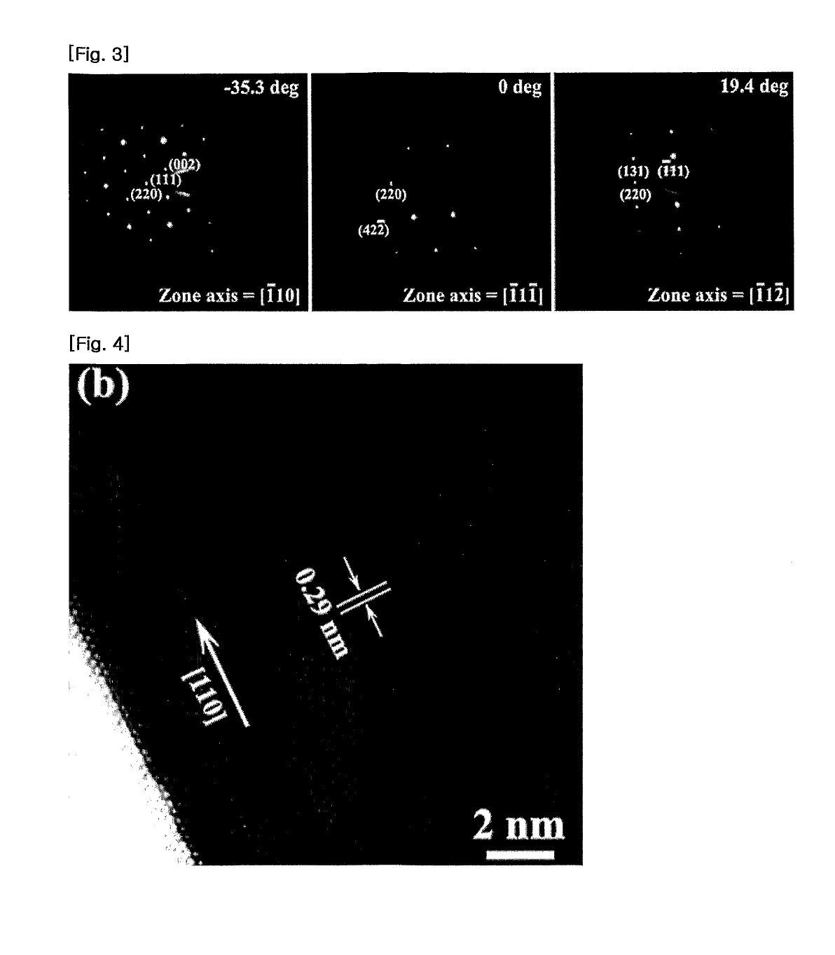

FIG. 3 shows SAED patterns with respect to 3 zone axis of the single Ag nanowire fabricated through Example 1 of the present invention. From the electronic diffraction patterns in FIG. 3, it can be appreciated that One Ag a nanowire is a single crystal body. From the a distance between a point of the zone axis (a transmitting point) and a diffraction point and the results of the electronic diffraction pattern according to the zone axis in FIG. 3, it can be appreciated that the fabricated Ag nanowire has a face centered cubic (FCC) structure and has a size of the unit cell which is identical to that of the bulk Ag.

FIG. 4 is a high resolution TEM (HRTEM) image showing the Ag nanowire. As can be appreciated from FIG. 4, the surface constituting the major axis of the smoothly curved Ag nanowire has an atomically rough structure and the growth direction of the Ag nanowire is <110> direction. Also, it can be appreciated that a space between (110) faces is 0.29 nm which is identical to the bulk Ag.

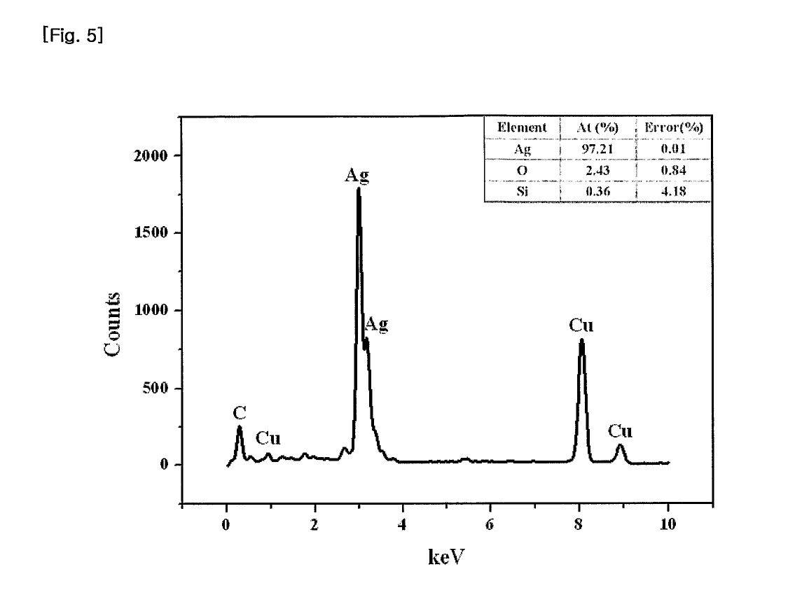

FIG. 5 is a result of component analysis for the Ag nanowire using an energy dispersive spectroscopy (EDS) attached to the TEM equipment. As can be appreciated from the result of FIG. 5, the fabricated nanowire is made of Ag alone except for substance subordinately measured due to the characteristic of the measuring equipment such as a grid.

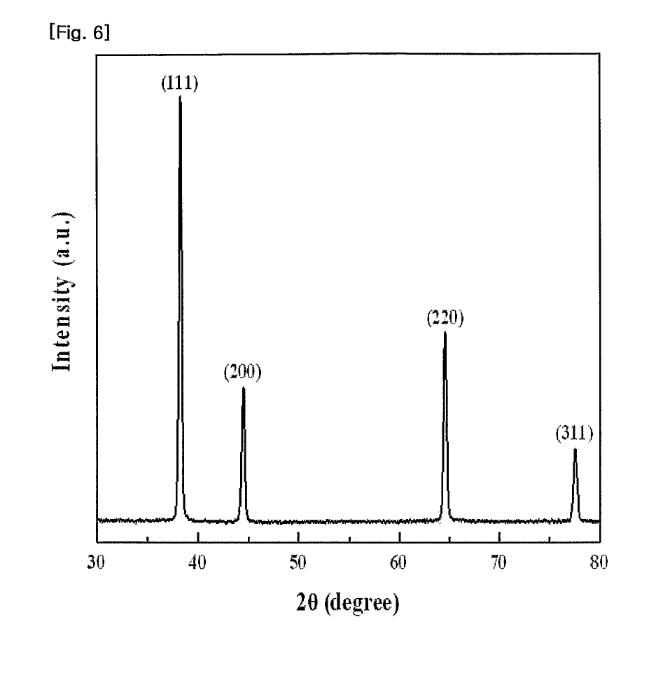

FIG. 6 is an X-ray diffraction (XRD) result of the Ag nanowire. The diffraction result is exactly agreed with the diffraction result of the bulk Ag without peak shift, and the fabricated Ag nanowire has a FCC structure.

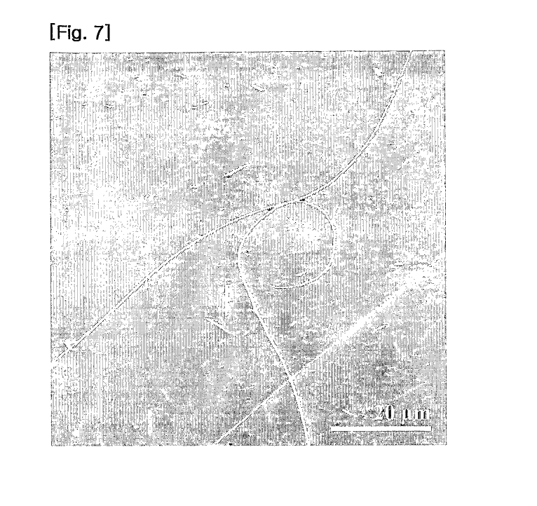

FIGS. 7 to 10 show results of measuring the Au nanowire fabricated through Example 2. FIG. 7 is a SEM image showing the Au nanowire fabricated on the sapphire single crystalline substrate. Similarly to the fabrication result for the Ag nanowire, it can be appreciated that a large amount of nanowires was formed in uniform size of tens micrometer separably from the sapphire single crystalline substrate, Ag nanowire having a shape extending straightly in a major axis direction of the nanowire and individually separable without agglomeration of the nanowires were formed, and a diameter of minor axis of the Au single crystalline nanowire is 50 to 150 nm and a length of the major axis thereof is greater than 50 μm.

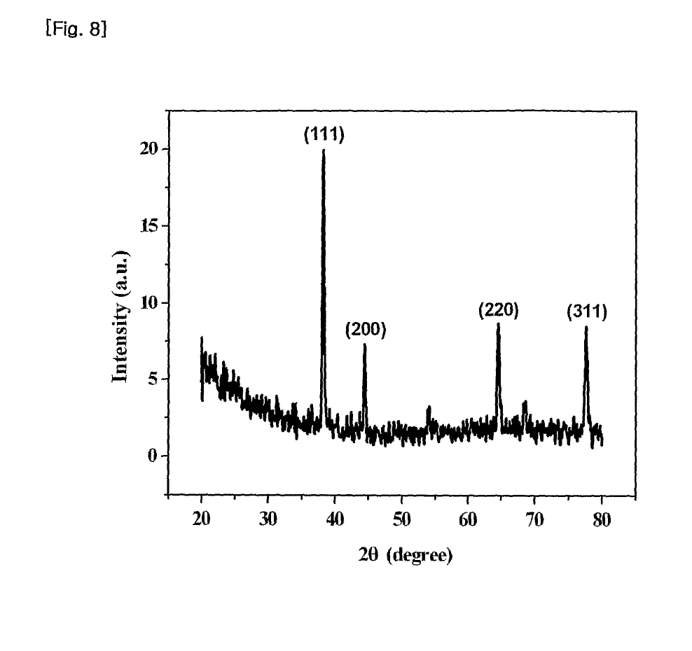

FIG. 8 is an XRD (X-Ray Diffraction) result of the Au nanowire. The diffraction result is exactly agreed with the diffraction result of the bulk Au without peak shift, and the fabricated Au nanowire has a FCC (Face Centered Cubic) structure.

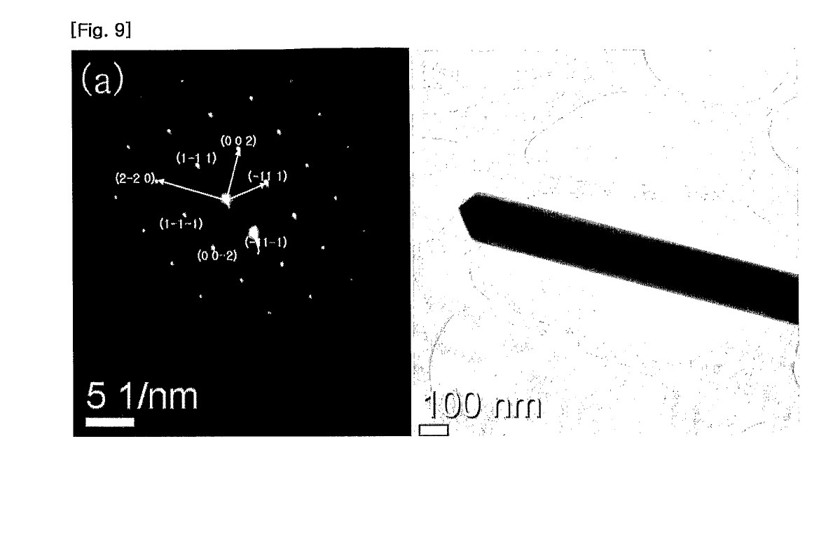

When observing the shape and structure of the fabricated Au nanowire using TEM, as can be appreciated from FIGS. 9a and 9b, the fabricated Au nanowire has a smooth surface and a section of a growth directional end of the Au single crystalline nanowire has a faceted shape unlike the Ag. Also, from SAED in FIG. 9a, it can be appreciated that the fabricated Au nanowire is a single crystal body formed of a single crystal, the growth direction (major axis) of the Au single crystalline nanowire is <110> direction, and each face forming the facet of the face faceted shaped nanowire is a low index face such as {111}, {110} and {100}.

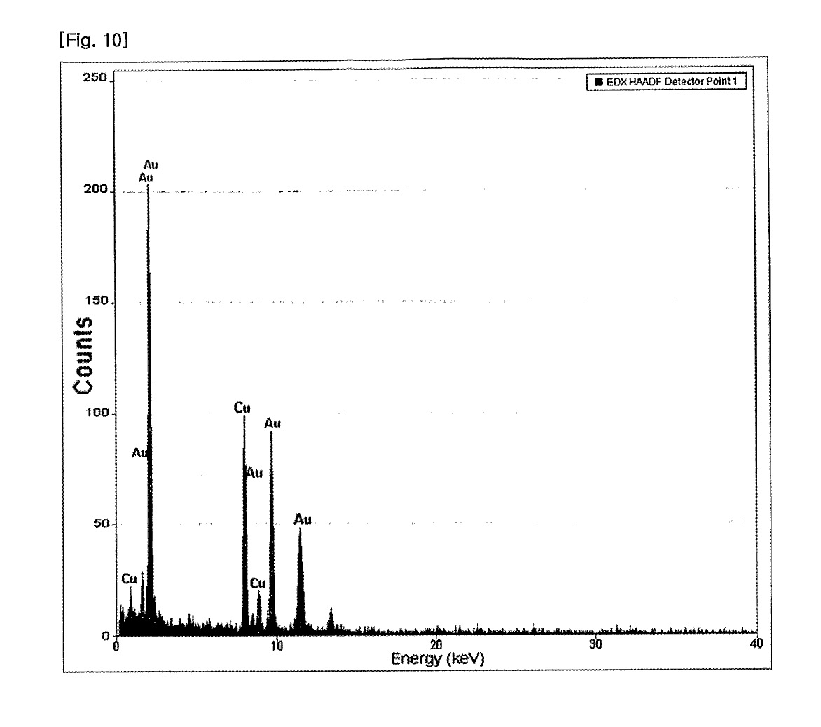

FIG. 10 is a result of component analysis for the Au nanowire using an EDS attached to the TEM equipment. As can be appreciated from the result of FIG. 10, the fabricated nanowire is made of Au alone except for substance subordinately measured due to the characteristic of the measuring equipment such as a grid.

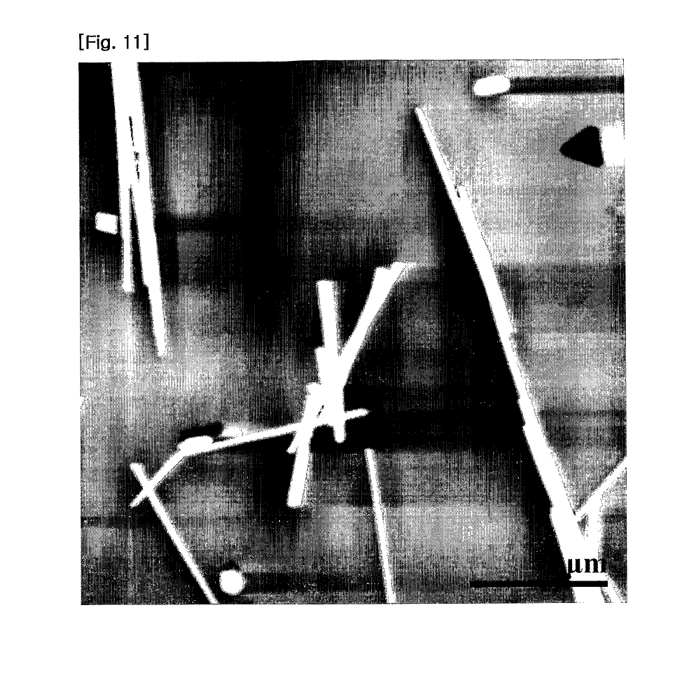

FIGS. 11 to 14 show results of measuring the Pd nanowire fabricated through Example 3. FIG. 11 is a SEM image showing the Pd nanowire fabricated on the sapphire single crystalline substrate. Similarly to the fabrication result for the Pd nanowire, it can be appreciated that a large amount of nanowires was formed in uniform size of several micrometer separably from the sapphire single crystalline substrate, Ag nanowire having a shape extending straightly in a major axis direction of the nanowire and individually separable without agglomeration of the nanowires were formed, and a diameter of minor axis of the Pd single crystalline nanowire is 50 to 150 nm and a length of the major axis thereof is greater than 5 μm.

FIG. 12 is an XRD result of the Pd nanowire. As can be appreciated from FIG. 12, the diffraction result of the fabricated Pd nanowire is agreed with the diffraction result of the bulk Pd, and the fabricated Pd nanowire has a FCC structure.

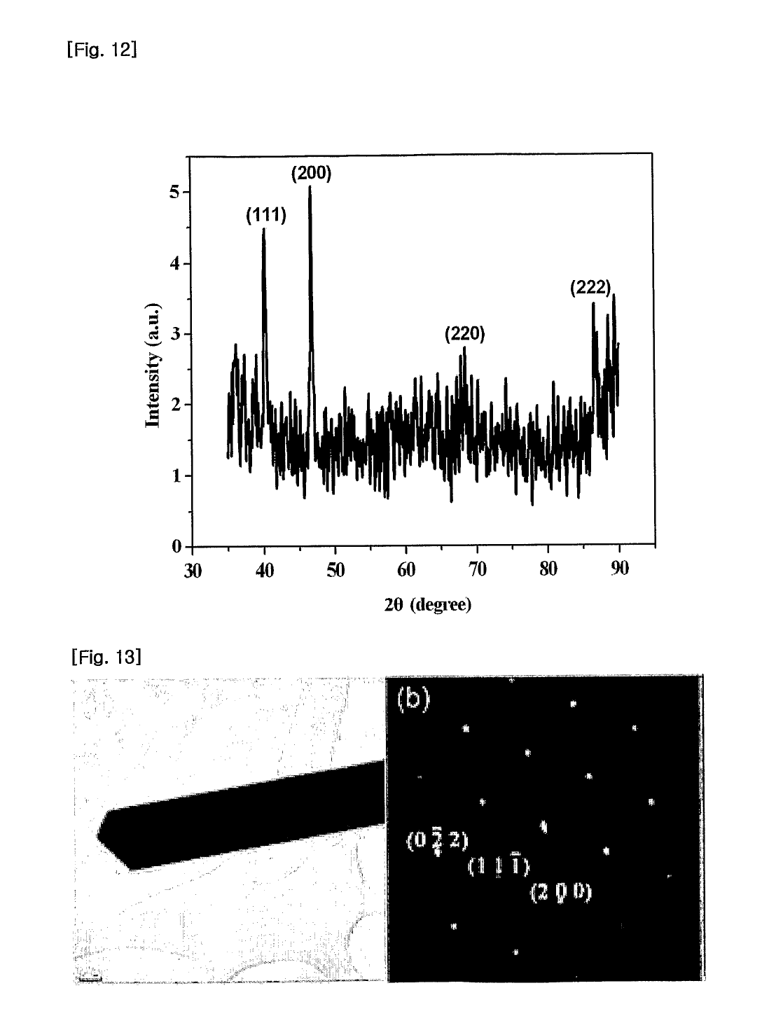

When observing the shape and structure of the fabricated Pd nanowire using TEM, as can be appreciated from FIGS. 13a and 13b, the fabricated Pd nanowire has a smooth surface and a section of a growth directional end of the Au single crystalline nanowire has a faceted shape unlike the Ag. Also, from SAED in FIG. 13a, it can be appreciated that the fabricated Pd nanowire is a single crystal body formed of a single crystal, the growth direction (major axis) of the Pd single crystalline nanowire is <110> direction, and each face forming the facet of the face faceted shaped nanowire is a low index face such as {111}, {110} and {100}.

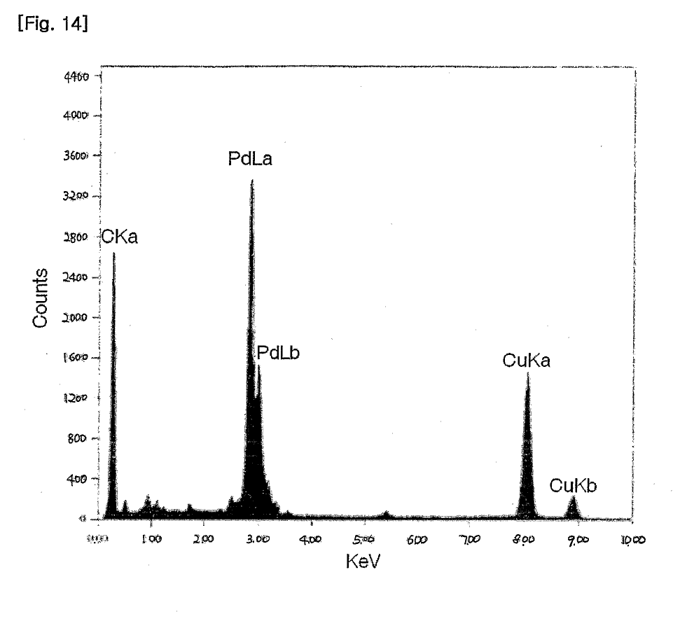

FIG. 14 is a result of component analysis for the Pd nanowire using an EDS attached to the TEM equipment. As can be appreciated from the result of FIG. 14, the fabricated nanowire is made of Pd alone except for substance subordinately measured due to the characteristic of the measuring equipment such as a grid.

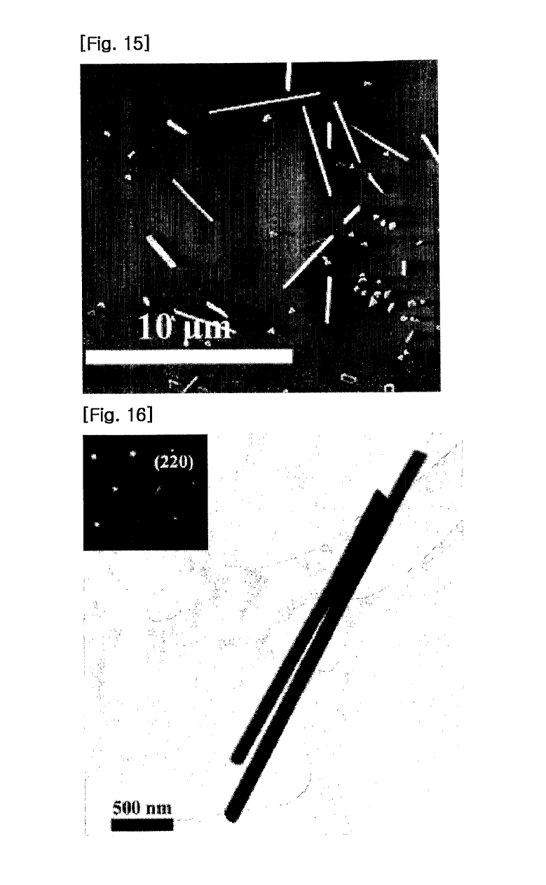

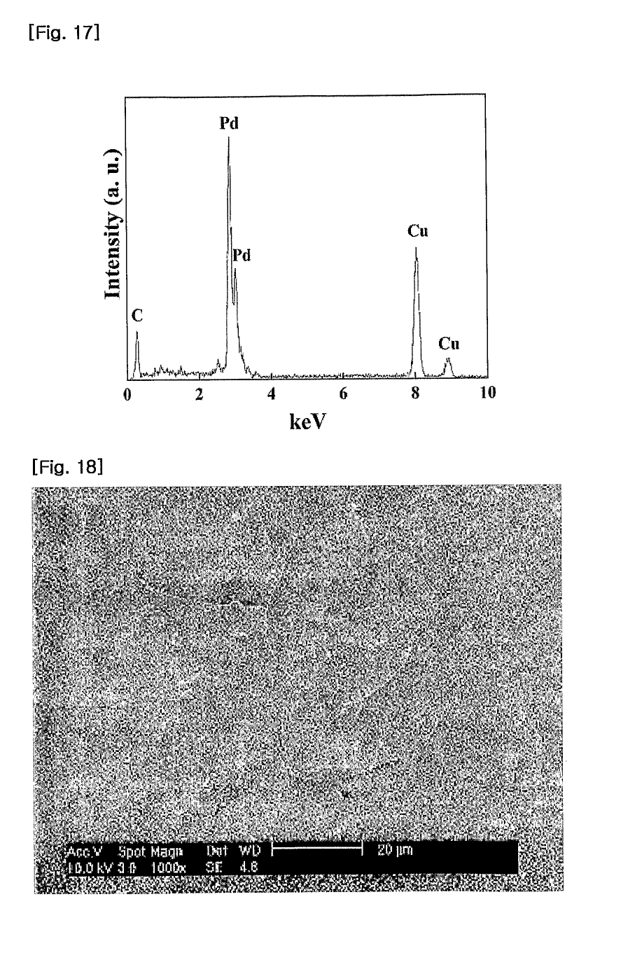

FIGS. 15 to 17 show results of measuring the Pd nanowire fabricated through Example 4. FIG. 15 is a SEM image showing the Pd nanowire fabricated on the sapphire single crystalline substrate using a Pd precursor. Similarly to the fabrication result using palladium oxide as a precursor, it can be appreciated that a large amount of nanowires was formed in a size of several micrometer separably from the sapphire single crystalline substrate, and Pd nanowire having a shape extending straightly in a major axis direction of the nanowire and individually separable without agglomeration of the nanowires were formed. As can be appreciated from FIG. 16, the fabricated Pd nanowire has a smooth surface. Also, from SAED shown at upper left in FIG. 16, it can be appreciated that the fabricated Pd nanowire is a single crystal body formed of a single crystal and the growth direction (major axis) of the Pd single crystalline nanowire is <110> direction. FIG. 17 is a result of component analysis for the Pd nanowire using an EDS attached to the TEM equipment. As can be appreciated from the result of FIG. 17, the fabricated nanowire is made of Pd alone except for substance subordinately measured due to the characteristic of the measuring equipment such as a grid.

As can be appreciated from Example 4 and the results of FIGS. 15 to 17, also when using the noble metal material as the precursor besides the noble metal oxide, high purity nanowire that has uniform size and is a high quality single crystal body and contains no impurities is fabricated separably from the substrate without agglomeration of the fabricated nanowires.

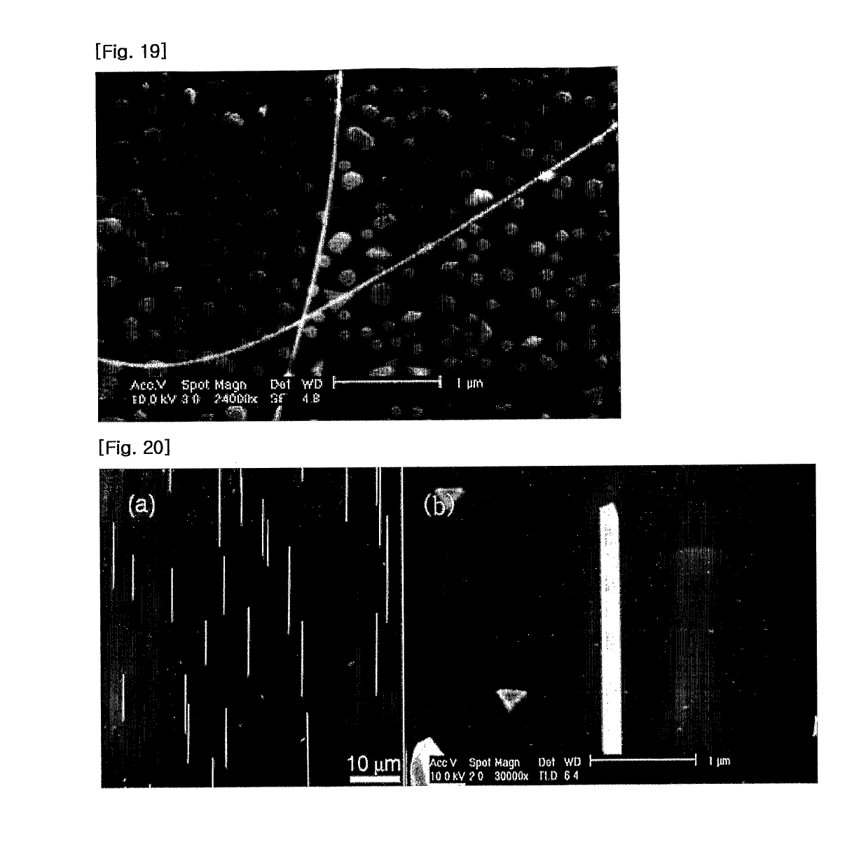

FIGS. 18 and 19 show results of measuring the Au nanowire fabricated through Example 5. FIG. 18 is a SEM image showing the Au nanowire fabricated on the sapphire single crystalline substrate using AuCl as the precursor and FIG. 19 is a high magnification SEM image. It can be appreciated that also when using AuCl as the precursor, a large amount of nanowires was formed in a size of several micrometer separably from the sapphire single crystalline substrate, and Au nanowire having a shape extending straightly in a major axis direction of the nanowire and individually separable without agglomeration of the nanowires were formed. From the analysis of results of EDS and electron diffraction using TEM of the Au nanowire fabricated through Example 5, single crystalline, high purity and high quality Au nanowire is fabricated similarly to Au nanowire fabricated through Example 2.

As described above, from the results of analysis for the noble metal nanowire fabricated through Examples 1 to 5, it can be appreciated that the noble metal nanowires of the present invention are, commonly and regardless of the used precursor, a high purity nanowire which have uniform sizes, are high quality single crystal body and contain no impurities. Also, it can be appreciated that a large amount of nanowires are formed and respective nanowires are not agglomerated and are individually separable.

Hereinafter, methods for fabricating a single crystalline noble metal nanowire having an orientation with the single crystalline substrate will be described in detail through Examples 6 to 14.

### Example 6

An Au single crystalline nanowire vertically oriented with the substrate was synthesized in a furnace using vapor phase transport method.

The furnace is divided into a front portion and a rear portion, which are independently provided with a heating element and a temperature controller. A tube in the furnace was formed of quartz having a size of 1 inch diameter and 60 cm length.

In a middle of the front portion of the furnace was located a boat-shaped receptacle of high purity alumina material containing 0.02 g of Au₂O₃ (Sigma-Aldrich, 334057) as a precursor and in a middle of the rear portion of the furnace was located a (0001) surface sapphire single crystalline substrate. Argon gas is inputted into the front portion of the furnace and discharged from the rear portion of the furnace, and the rear portion of the furnace is provided with a vacuum pump. A pressure within the quartz tube was maintained at 5 torr using the vacuum pump and Ar was allowed to flow in 100 sccm by using a MFC.

Heat treatment was carried out for 30 minutes in a state that the temperature of the front portion of the furnace (alumina boat containing the precursor) is maintained at 100° C. and the temperature of the rear portion of the furnace at 900° C., thereby fabricating Au single crystalline nanowire.

### Example 7

A Pd single crystalline nanowire vertically oriented with the substrate was synthesized in a furnace using vapor phase transport method.

The Pd nanowire was fabricated using the same condition and apparatus of Example 6, except for the heat treatment temperature, the precursor, the flow rate of the inert gas and the pressure.

0.05 g of PdO (Sigma-Aldrich, 203971) was used as the precursor, and the pressure in the quartz tube was maintained at 6 torr using the vacuum pump.

Heat treatment was carried out for 30 minutes in a state that Ar flows in 500 sccm, the temperature of the front portion of the furnace (alumina boat containing the precursor) is maintained at 1100° C. and the temperature of the rear portion of the furnace (sapphire substrate) is maintained at 900° C., thereby fabricating Pd single crystalline nanowire.

### Example 8

An Au single crystalline nanowire horizontally oriented with the substrate was synthesized in a furnace using vapor phase transport method.

The Au single crystalline nanowire was fabricated using the same condition and apparatus of Example 6, except for the heat treatment temperature, the pressure and the flow rate of the inert gas.

The pressure in the quartz furnace was maintained at 17 torr using the vacuum pump, and heat treatment was carried out for 30 minutes in a state that Ar flows in 80 sccm, the temperature of the front portion of the furnace (alumina boat containing the precursor) is maintained at 1100° C. and the temperature of the rear portion of the furnace (sapphire substrate) is maintained at 850° C., thereby fabricating the Au single crystalline nanowire.

### Example 9

An Au single crystalline nanowire horizontally oriented with the substrate was synthesized in a furnace using vapor phase transport method.

The Au single crystalline nanowire was fabricated using the same condition and apparatus of Example 8, except for using a (11-20) face single crystalline sapphire substrate.

### Example 10

A Pd single crystalline nanowire horizontally oriented with the substrate was synthesized in a furnace using vapor phase transport method.

The Pd single crystalline nanowire was fabricated using the same condition and apparatus of Example 7, except for the heat treatment temperature, the pressure and the flow rate of the inert gas.

The pressure in the quartz tube was maintained at 20 torr using the vacuum pump, and heat treatment was carried out for minutes in a state that Ar flows in 100 sccm, the temperature of the front portion of the furnace (alumina boat containing the precursor) is maintained at 1100° C. and the temperature of the rear portion of the furnace (sapphire substrate) is maintained at 850° C., thereby fabricating the Au single crystalline nanowire.

### Example 11

An Au single crystalline nanowire vertically oriented with the substrate was synthesized using Au as the precursor.

The Au single crystalline nanowire was fabricated using the same condition and apparatus of Example 6, except for using 0.02 g of Au as the precursor.

### Example 12

A Pd single crystalline nanowire vertically oriented with the substrate was synthesized using Pd as the precursor.

The Pd single crystalline nanowire was fabricated using the same condition and apparatus of Example 7, except for using 0.05 g of Pd as the precursor.

### Example 13

An Au single crystalline nanowire horizontally oriented with the substrate was synthesized using Au as the precursor.

The Au single crystalline nanowire was fabricated using the same condition and apparatus of Example 8, except for using Au as the precursor.

### Example 14

A Pd single crystalline nanowire horizontally oriented with the substrate was synthesized using Pd as the precursor.

The Pd single crystalline nanowire was fabricated using the same condition and apparatus of Example 10, except for using Pd as the precursor.

Physical properties of the nanowire fabricated in Example 6 are similar to that of the nanowire fabricated in Example 11; physical properties of the nanowire fabricated in Example 7 are similar to that of the nanowire fabricated in Example 12; physical properties of the nanowire fabricated in Example 8 are similar to that of the nanowire fabricated in Example 13; and physical properties of the nanowire fabricated in Example 10 are similar to that of the nanowire fabricated in Example 14. Therefore, properties of the single crystalline nanowire fabricated and analyzed will be described hereinafter with respect to Examples 6 to 10.

By analyzing the single crystalline noble metal nanowires fabricated through Examples 6 to 10, quality, shape and purity of the single crystalline noble metal nanowires having an orientation with the substrate were analyzed.

FIGS. 20 to 23 show results of measuring the Au nanowire fabricated through Example 6.

FIG. 20a is a SEM image showing Au nanowire fabricated on the sapphire single crystalline substrate. As can be appreciated from FIG. 20, the Au nanowire is grown and arranged vertically with respect to the surface of the single crystalline substrate. Also, it can be appreciated that a large amount of nanowires was formed and the Au nanowire having a shape extending straight in a major axis direction and individually separable without agglomeration of the nanowires were formed. Also, through the high resolution SEM in FIG. 20b, it can be appreciated that the Au nanowire has macroscopically a faceted shape.

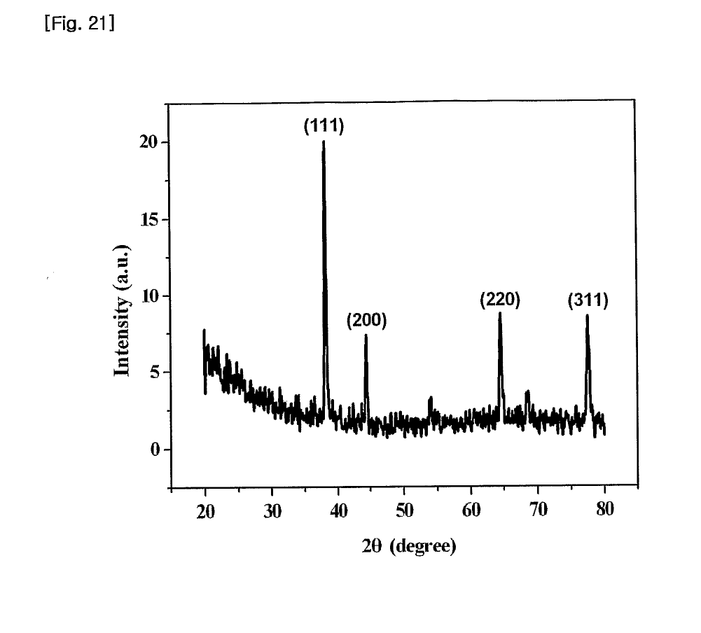

FIG. 21 is an XRD result of the Au nanowire. It can be appreciated that the diffraction result is exactly agreed with the diffraction result of the bulk Au without peak shift and the fabricated Au nanowire has a FCC structure.

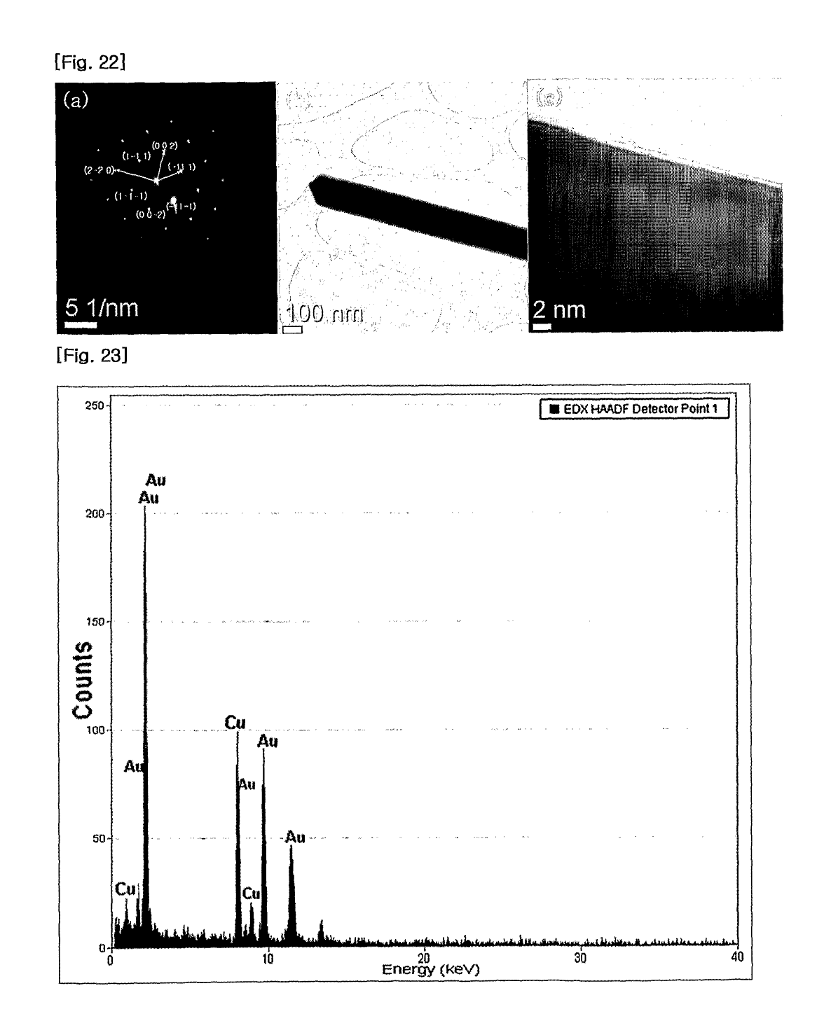

When observing the shape and structure of the fabricated Au nanowire using TEM, as can be appreciated from FIGS. 22a to 22c, the fabricated Au nanowire has a smooth surface and a faceted shape. From SAED in FIG. 22a, it can be appreciated that the fabricated Au nanowire is a single crystal body formed of a single crystal. From FIGS. 22a and 22b, it can be appreciated that the growth direction (major axis) of the Au single crystalline nanowire is <110> direction. Also, from the result in FIG. 22c, it can be appreciated that the nanowire is a complete single crystal.

From the results in FIGS. 20 to 22c, it can be appreciated that the section of the Au single crystalline nanowire perpendicular to the growth direction has a faceted shape in which inclination of the tangent line on the periphery of the section is discontinuously varied, and each face forming the faceted surface of the faceted shaped nanowire is a low index face such as {111}, {110} and {100}.

FIG. 23 is a result of component analysis for the Au nanowire using an EDS attached to the TEM equipment. As can be appreciated from the result of FIG. 23, the fabricated nanowire is made of Au alone except for substance subordinately measured due to the characteristic of the measuring equipment such as a grid.

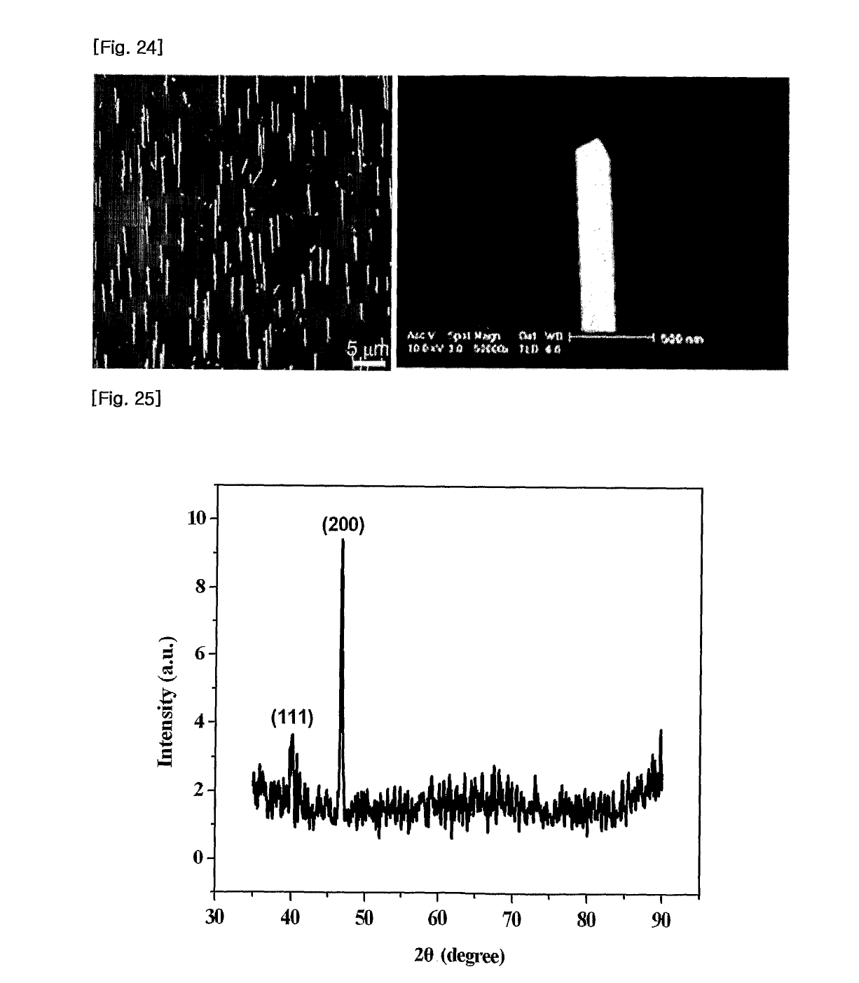

FIGS. 24 to 27 show results of measuring the Pd nanowire fabricated through Example 7.

FIG. 24a is a SEM image showing Pd nanowire fabricated on the sapphire single crystalline substrate. It can be appreciated that a large amount of the nanowires having a diameter of 50 to 150 nm and a length of 5˜10 μm is grown and arranged vertically with respect to the surface of the single crystalline substrate. It can be appreciated that the Pd nanowire having a shape extending straight in a major axis direction and individually separable without agglomeration of the nanowires were formed. Also, through the high resolution SEM in FIG. 24b, it can be appreciated that the Pd nanowire has macroscopically a faceted shape.

FIG. 25 is an XRD result of the Pd nanowire. It can be appreciated that the diffraction result of the fabricated Pd nanowire is agreed with the diffraction result of the bulk Pd and the fabricated Pd nanowire has a FCC structure.

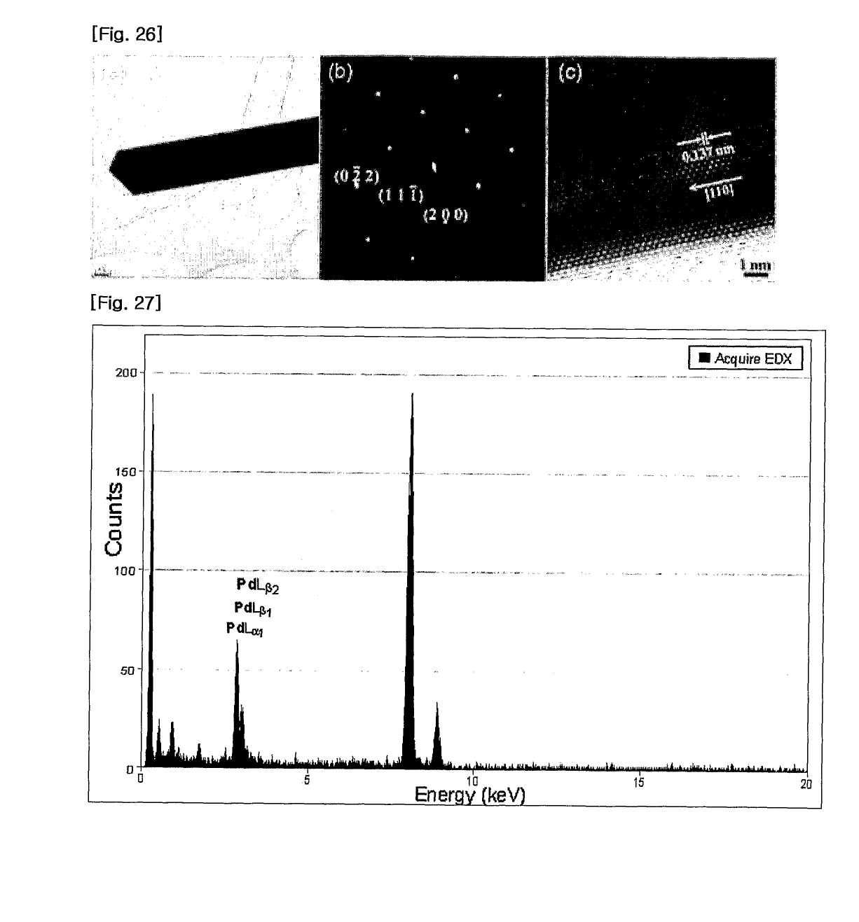

When observing the shape and structure of the fabricated Pd nanowire using TEM, as can be appreciated from FIGS. 26a to 26c, the fabricated Pd nanowire has a smooth surface and a faceted shape. From SAED in FIG. 26b, it can be appreciated that the fabricated Pd nanowire is a single crystal body formed of a single crystal, and the growth direction (major axis) of the Pd single crystalline nanowire is <110> direction. It can be appreciated that each face forming the faceted surface of the faceted shaped nanowire is a low index face such as {111}, {110} and {100}. Also, from the HRTEM image in FIG. 26c, it can be appreciated that the fabricated single crystalline nanowire.

FIG. 27 is a result of component analysis for the Pd nanowire using an EDS attached to the TEM equipment. As can be appreciated from the result of FIG. 27, the fabricated nanowire is made of Pd alone except for substance subordinately measured due to the characteristic of the measuring equipment such as a grid.

As described above, from the results of analysis for the noble metal nanowire fabricated through Examples 6 and 7, it can be appreciated that the noble metal nanowires of the present invention are, commonly and regardless of the material, a high purity nanowire which are grown and arranged vertically with respect to the surface of the single crystalline substrate, are high quality single crystal body and contain no impurities. Also, it can be appreciated that a large amount of nanowires are formed and respective nanowires are not agglomerated and are individually separable. Further, it can be appreciated that, in crystallographical characteristics, the single crystalline noble metal nanowire has the same crystalline structure as noble metal bulk and the single crystalline nanowire has a growth direction (major axis) of <110> direction and a faceted shape.

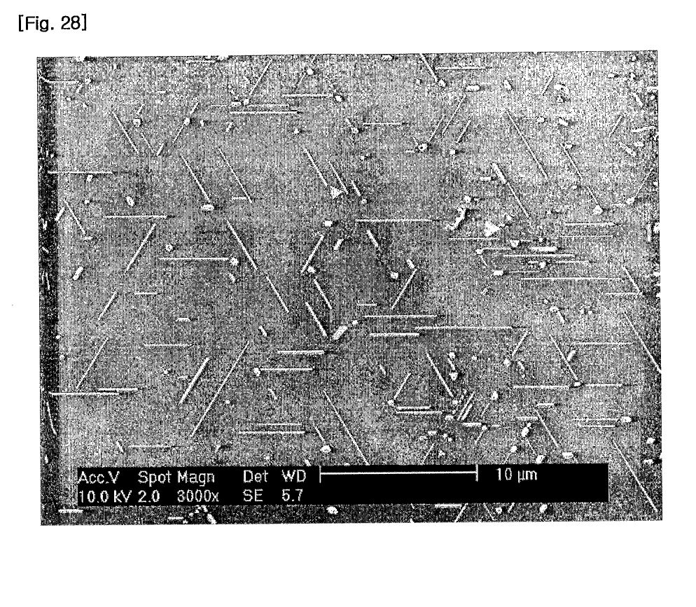

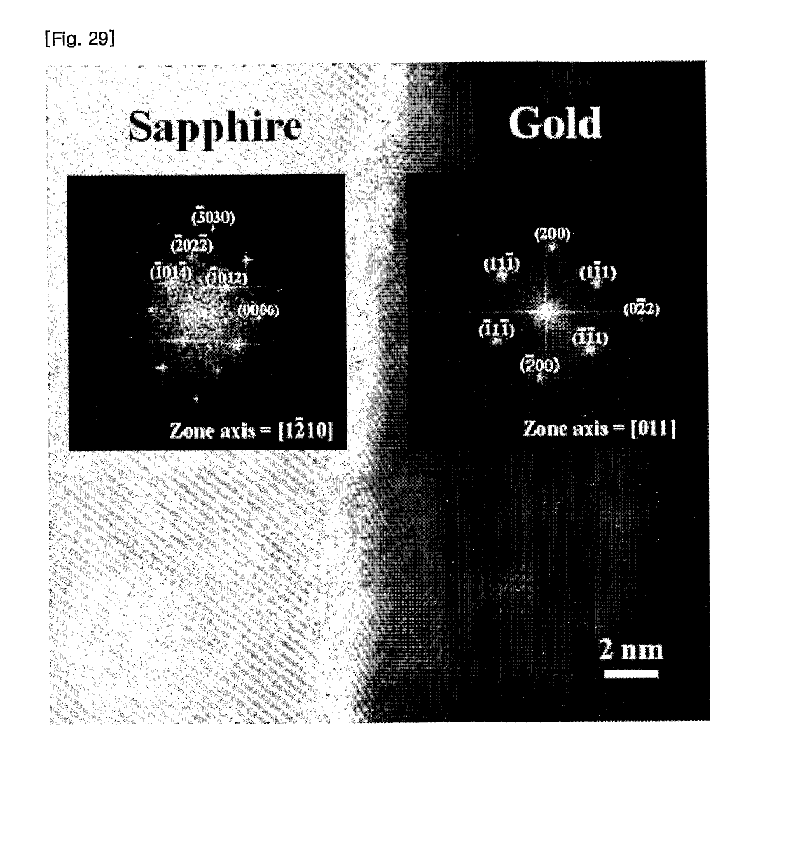

FIGS. 28 and 29 show results of measuring the Au nanowire fabricated through Example 8.

FIG. 28 is a SEM image showing Au nanowire fabricated on the sapphire single crystalline substrate. It can be appreciated that a large amount of the nanowires grown and arranged horizontally with respect to the surface of the single crystalline substrate is fabricated.

FIG. 29 is a HRTEM image showing an interface between the Au nanowire and the sapphire substrate. As can be appreciated from the electron diffraction pattern at upper right in FIG. 29, the fabricated Au nanowire is formed of pure single crystal and has a FCC structure which is identical to the bulk Au. Also, from the result in FIG. 29, the result of observation of crystallographic relationship between the fabricated Au nanowire and the substrate using TEM, it can be appreciated that (110) face of the fabricated Au nanowire is epitaxial with (0001) face, i.e. the surface of the sapphire single crystal.

It can be appreciated that the Au single crystalline nanowire grown epitaxially on the surface of the sapphire single crystal has a growth direction of <110> and the major axis (<110>) of the Au nanowire is parallel to <11-20> direction of the surface of the sapphire single crystal. Accordingly, it can be appreciated that a plurality of Au nanowires horizontally grown as shown in FIG. 28 have a triangular or hexagonally arranged structure in six directions that are crystallographically identical to <11-20>.

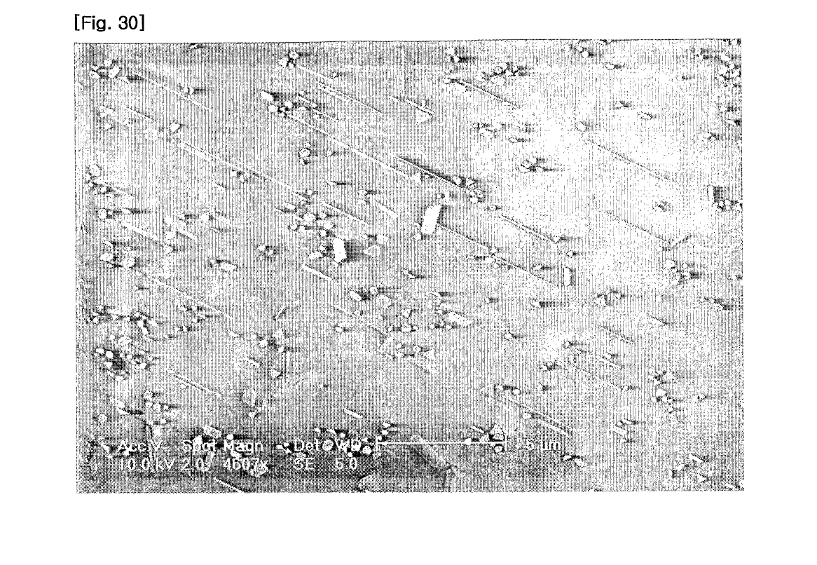

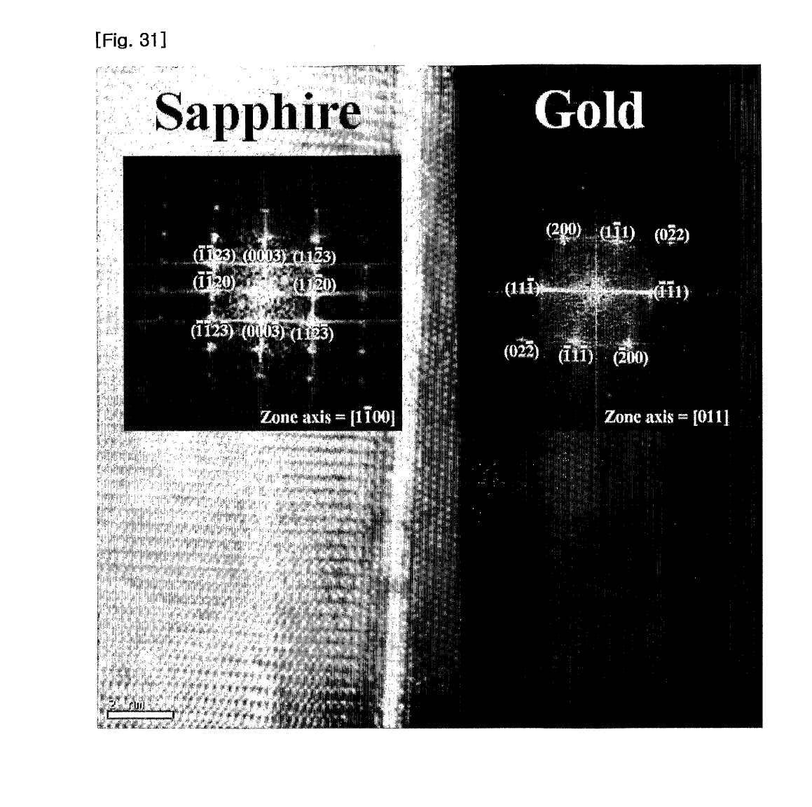

FIGS. 30 and 31 show results of measuring the Au nanowire fabricated through Example 9.

FIG. 30 is a SEM image showing Au nanowire fabricated on the A-face sapphire single crystalline substrate. It can be appreciated that a large amount of the nanowires grown and arranged horizontally with respect to the surface of the single crystalline substrate is fabricated. However, unlike Example 8 having a structure in which the major axis (<110>) of the Au nanowire is arranged in six directions crystallographically identical to <11-20>, Au nanowire arranged in single direction was fabricated.

FIG. 31 is a HRTEM image showing an interface between the Au nanowire and the sapphire substrate. As can be appreciated from the electron diffraction pattern at upper right in FIG. 31, the fabricated Au nanowire is formed of pure single crystal and has a FCC structure which is identical to the bulk Au. Also, from the result of observation of crystallographic relationship between the fabricated Au nanowire and the substrate using TEM, it can be appreciated that, similarly to Example 8, the Au single crystalline nanowire grown has a growth direction of <110>, (11-1) face of the fabricated Au nanowire is epitaxial with (11-20) face, i.e. the surface of the sapphire single crystal and the major axis (<110>) of the Au nanowire is parallel to <0001> direction of the A-face sapphire single crystal. Accordingly, it can be appreciated that a plurality of Au nanowires horizontally grown as shown in FIG. 30 is arranged in single direction of <0001>.

Further, from the results of component analysis for the Au nanowires fabricated through Examples 8 and 9 using an EDS attached to the TEM equipment, it can be appreciated that, similarly to Example 6, pure Au nanowire was fabricated which is made of Au alone except for substance subordinately measured due to the characteristic of the measuring equipment such as a grid.

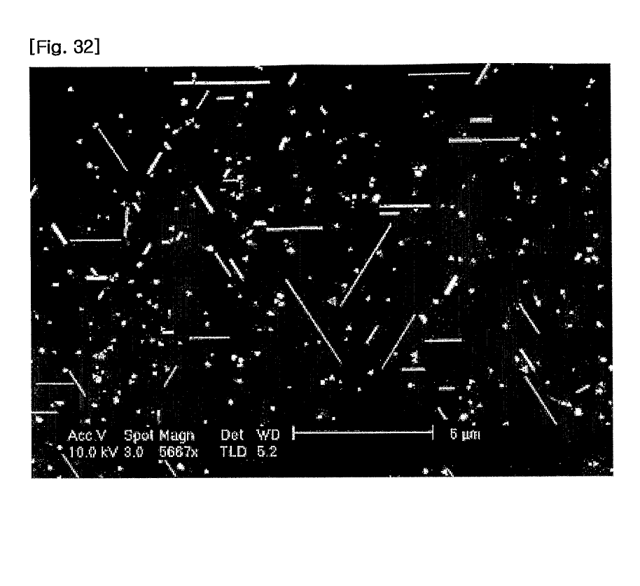

FIG. 32 is a SEM image showing the PD nanowire fabricated through Example 10. Similarly to Au nanowires of Examples 8 and 9 that are grown parallel to the substrate, Pd nanowire grown parallel to the substrate was fabricated. From the result of analysis for crystalline structure using TEM, it can be appreciated that single crystalline Pd nanowire was fabricated similarly to Example 7. Also, from the component analysis using EDS attached to TEM equipment, it can be appreciated that pure Pd nanowire made of Pd alone was fabricated.

Through Example 6 to 10, it can be appreciated that high quality and high purity noble metal nanowire, which is fabricated under non-catalytic condition using a precursor containing noble metal oxide, noble metal material or noble metal halide, is pure single crystal body and has few internal defect, is formed on the upper portion of the substrate with a predetermined orientation. Also, it can be appreciated that this orientation is controlled by kinds of the precursor, kinds of the single crystalline substrate, the surface direction of the single crystalline substrate, the heat treatment temperature, the flow rate of the inert gas, the pressure or a combination thereof.

According to the method for fabricating a noble metal nanowire of the present invention and the noble metal nanowire fabricated by the fabrication method of the present invention, it is possible to control the orientation with the surface of the substrate and size and shape of the nanowire; it is possible to provide a base for studying physical, optical and electromagnetic properties of the nanowire itself by providing a large amount of high purity and high quality nanowire through reproducible and simple process; and it is possible to enhance properties of electric devices, optical devices or magnetic devices and reduce the size thereof using the noble metal nanowire chemically stable and having excellent electric and thermal conductivities among metals. Particularly, it can be provided in a spectrometer using surface properties of the noble metal nanowire, a bio sensor, a sensor for detecting light, electricity, heat, vibration or combination thereof and it is thus possible to control detection properties and enhance sensitivity, accuracy and reproducibility of the sensor. Also, it can be utilized as a MEMS structural body and a three dimensional memory device using vertical arrangement with respect to the surface of the single crystalline substrate.

While the present invention has been described with respect to the specific embodiments, it will be apparent to those skilled in the art that various changes and modifications may be made without departing from the spirit and scope of the invention as defined in the following claims.

### INDUSTRIAL APPLICABILITY

Since it is possible to fabricate a noble metal nanowire using non-catalytic vapor phase transport method, the method of the present invention has advantages that the process is simple and reproducible, the fabricated nanowire is a defect free and impurity free, high quality and high purity noble metal nanowire of complete single crystal state, and it is possible to mass produce noble metal nanowire having uniform size and not agglomerated on the single crystalline substrate. Also, the method of the present invention has an advantage that it is possible to fabricate so that the single crystalline substrate and the fabricated noble metal nanowire have a specific orientation with each other.

Since the noble metal nanowire can be massively provided using controllable, reproducible and simple fabrication process, it is possible to provide a base for studying physical, optical and electromagnetic properties of the nanowire itself. Since it is possible to provide high purity and high quality Ag nanowire, Au nanowire and Pd nanowire chemically stable and having excellent electric and thermal conductivities among metals, it is possible to utilize them in a high sensitive, high efficient electric devices, optical devices or magnetic devices, particularly in a spectrometer using surface properties of the noble metal nanowire, a bio sensor, a sensor for detecting light, electricity, heat, vibration or combination thereof.

Since the noble metal nanowire having a specific orientation with the substrate can be massively provided using controllable, reproducible and simple fabrication process, it is possible to provide a base for studying physical, optical and electromagnetic properties of the nanowire itself. Since it is possible to provide high purity and high quality Ag nanowire, Au nanowire and Pd nanowire chemically stable and having excellent electric and thermal conductivities among metals, it is possible to utilize them in a high sensitive, high efficient electric devices, optical devices or magnetic devices. Particularly, it is possible to utilize effectively the noble metal nanowire having an orientation with the surface of the substrate in a three dimensional MEMS structural body or a three dimensional memory device.

1. A method for fabricating a single crystal noble metal nanowire, wherein a precursor containing noble metal oxide, noble metal material or noble metal halide located at a front portion of a furnace and a semiconductive or nonconductive single crystal substrate located at a rear portion of the furnace are heat treated in an inert gas flow atmosphere, thereby forming the single crystal noble metal nanowire on the single crystal substrate.

2. The method as set forth in claim 1, wherein the inert gas flows in 100 to 600 sccm from the front portion of the furnace to the rear portion of the furnace.

3. The method as set forth in claim 2, wherein the heat treatment is carried out at a pressure of 2 to 50 torr.

4. The method as set forth in claim 3, wherein the temperature of the front portion of the furnace is equal to or greater than the temperature of the rear portion of the furnace, and the temperature difference by subtracting the temperature of the rear portion of the furnace from the temperature of the front portion of the furnace is 0 to 700° C.

5. The method as set forth in claim 1, wherein the noble metal oxide is selected from silver oxide, gold oxide and palladium oxide, and the noble metal material is selected from silver, gold and palladium.

6. The method as set forth in claim 5, wherein the inert gas flows in 400 to 600 sccm from the front portion of the furnace to the rear portion of the furnace.

7. The method as set forth in claim 1, wherein the noble metal halide is selected from noble metal fluoride, noble metal chloride, noble metal bromide and noble metal iodide.

8. The method as set forth in claim 7, wherein the inert gas flows in 100 to 300 sccm from the front portion of the furnace to the rear portion of the furnace.

9. The method as set forth in claim 1, wherein the precursor further contains transition metal material.

10. The method as set forth in claim 1, wherein the single crystalline substrate is a sapphire substrate or a silicon substrate.

11. The method as set forth in claim 3, wherein the precursor is silver oxide, silver or silver halide, and the single crystalline noble metal nanowire is Ag nanowire.

12. The method as set forth in claim 11, wherein the precursor is maintained at 850 to 1050° C. and the single crystalline substrate is maintained at 400 to 600° C.

13. The method as set forth in claim 3, wherein the precursor is gold oxide, gold or gold halide, and the single crystalline noble metal nanowire is Au nanowire.

14. The method as set forth in claim 13, wherein the precursor is maintained at 1000 to 1200° C. and the single crystalline substrate is maintained at 900 to 1000° C.

15. The method as set forth in claim 3, wherein the precursor is palladium oxide, palladium or palladium halide, and the single crystalline noble metal nanowire is Pd nanowire.

16. The method as set forth in claim 15, wherein the precursor is maintained at 1000 to 1200° C. and the single crystalline substrate is maintained at 900 to 1000° C.

17. A single crystalline noble metal nanowire fabricated by the method as set forth in claim 1.

18. The single crystalline noble metal nanowire as set forth in claim 17, wherein the single crystalline noble metal nanowire is Ag single crystalline nanowire.

19. The single crystalline noble metal nanowire as set forth in claim 18, wherein the Ag single crystalline nanowire has a face centered cubic (FCC) structure.

20. The single crystalline noble metal nanowire as set forth in claim 18, wherein in a section of the Ag single crystalline nanowire perpendicular to the growth direction, an inclination of the tangent line on a periphery of the section is continuously varied

21. The single crystalline noble metal nanowire as set forth in claim 20, wherein the section is circular.

22. The single crystalline noble metal nanowire as set forth in claim 18, wherein a section of a growth directional end of the Ag single crystalline nanowire is elliptic.

23. The single crystalline noble metal nanowire as set forth in claim 17, wherein the single crystalline noble metal nanowire is Au single crystalline nanowire.

24. The single crystalline noble metal nanowire as set forth in claim 23, wherein the Au single crystalline nanowire has a FCC structure.

25. The single crystalline noble metal nanowire as set forth in claim 17, wherein the single crystalline noble metal nanowire is Pd single crystalline nanowire.

26. The single crystalline noble metal nanowire as set forth in claim 25, wherein the Pd single crystalline nanowire has a FCC structure.

27. A single crystalline noble metal nanowire, wherein the single crystalline noble metal nanowire is fabricated under a non-catalytic condition using a precursor containing noble metal oxide, noble metal material or noble metal halide and has an orientation with a surface of a semiconductive or nonconductive single crystal substrate.

28. The single crystalline noble metal nanowire as set forth in claim 27, wherein the orientation is a vertical or horizontal orientation.

29. The single crystalline noble metal nanowire as set forth in claim 27, wherein the noble metal oxide is selected from gold oxide and palladium oxide, the noble metal material is selected from gold and palladium, and the noble metal halide is selected from gold halide and palladium halide.

30. The single crystalline noble metal nanowire as set forth in claim 28, wherein the single crystalline noble metal nanowire is grown vertically with respect to the single crystalline substrate.

31. The single crystalline noble metal nanowire as set forth in claim 30, wherein the precursor is gold oxide or gold, and the vertically grown single crystalline noble metal nanowire is Au single crystalline nanowire.

32. The single crystalline noble metal nanowire as set forth in claim 31, wherein the Au single crystalline nanowire has a FCC structure and a direction of a major axis thereof is <110>.

33. The single crystalline noble metal nanowire as set forth in claim 30, wherein the precursor is palladium oxide or palladium, and the vertically grown single crystalline noble metal nanowire is Pd single crystalline nanowire.

34. The single crystalline noble metal nanowire as set forth in claim 33, wherein the Pd single crystalline nanowire has a FCC structure and a direction of a major axis thereof is <110>.

35. The single crystalline noble metal nanowire as set forth in claim 30, wherein the single crystalline noble metal nanowire has the same crystalline structure as noble metal bulk, and has a faceted shape.

36. The single crystalline noble metal nanowire as set forth in claim 30, wherein the single crystalline noble metal nanowire is grown vertically with respect to the surface of the substrate in a state that the precursor is maintained at 1000 to 1200° C., the single crystalline substrate is maintained at 850 to 1100° C., the inert gas flows in 50 to 200 sccm at a pressure of 3 to 8 torr from a front portion of a furnace to a rear portion of the furnace.

37. The single crystalline noble metal nanowire as set forth in claim 28, wherein the single crystalline noble metal nanowire is grown horizontally parallel to the single crystalline substrate.

38. The single crystalline noble metal nanowire as set forth in claim 37, wherein the precursor is gold oxide or gold, and the single crystalline noble metal nanowire grown horizontally parallel to the surface of the substrate is Au single crystalline nanowire.

39. The single crystalline noble metal nanowire as set forth in claim 38, wherein the single crystalline substrate is {0001} surface sapphire substrate, and the {0001} face of the substrate and {110} face of the FCC structure of the Au nanowire are parallel to each other.

40. The single crystalline noble metal nanowire as set forth in claim 38, wherein the single crystalline substrate is {11-20} surface sapphire substrate, and the {11-20} face of the substrate and {111} face of the FCC structure of the Au nanowire are parallel to each other.

41. The single crystalline noble metal nanowire as set forth in claim 37, wherein the precursor is palladium oxide or palladium, and the single crystalline noble metal nanowire grown horizontally parallel to the surface of the substrate is Pd single crystalline nanowire.

42. The single crystalline noble metal nanowire as set forth in claim 41, wherein the Pd single crystalline nanowire has a FCC structure.

43. The single crystalline noble metal nanowire as set forth in claim 41, wherein the single crystalline substrate is {0001} surface sapphire substrate.

44. The single crystalline noble metal nanowire as set forth in claim 37, wherein the single crystalline noble metal nanowire is grown parallel to the surface of the substrate in a state that the precursor is maintained at 1000 to 1200° C., the single crystalline substrate is maintained at 800 to 950° C., the inert gas flows in 50 to 200 sccm at a pressure of 15 to 20 torr from a front portion of a furnace to a rear portion of the furnace.

45. The single crystalline noble metal nanowire as set forth in claim 27, wherein the single crystalline substrate is a sapphire single crystalline substrate.

46. A method for fabricating a single crystal noble metal nanowire, wherein a precursor containing noble metal oxide or noble metal halide located at a front portion of a furnace and a semiconductive or nonconductive single crystal substrate located at a rear portion of the furnace are heat treated in an inert gas flow atmosphere at a predetermined pressure, thereby forming the single crystal noble metal nanowire having an orientation with a substrate of the single crystal substrate.

47. The method as set forth in claim 46, wherein a major axis of the single crystal noble metal nanowire has a vertical or horizontal orientation with the substrate of the single crystal substrate.

48. The method as set forth in claim 47, wherein the orientation is controlled by kinds of the precursor, kinds of the single crystalline substrate, surface direction of the single crystalline substrate, the heat treatment temperature, the flow rate of the inert gas, the pressure or combination thereof.

49. The method as set forth in claim 46, wherein the single crystal noble metal nanowire is grown vertically with respect to the substrate of the single crystal substrate.

50. The method as set forth in claim 49, wherein the precursor is maintained at 1000 to 1200° C. and the single crystalline substrate is maintained at 850 to 1100° C.

51. The method as set forth in claim 50, wherein the inert gas flows in 50 to 200 sccm from the front portion of the furnace to the rear portion of the furnace.

52. The method as set forth in claim 51, wherein the heat treatment is carried out at a pressure of 3 to 8 torr.

53. The method as set forth in claim 46, wherein the single crystal noble metal nanowire is grown horizontally parallel to the substrate of the single crystal substrate.

54. The method as set forth in claim 53, wherein the precursor is maintained at 1000 to 1200° C. and the single crystalline substrate is maintained at 800 to 950° C.

55. The method as set forth in claim 54, wherein the inert gas flows in 50 to 200 sccm from the front portion of the furnace to the rear portion of the furnace.

56. The method as set forth in claim 55, wherein the heat treatment is carried out at a pressure of 15 to 20 torr.

57. The method as set forth in claim 46, wherein the noble metal oxide is selected from gold oxide and palladium oxide and the noble metal material is selected from gold and palladium.

58. The method as set forth in claim 46, wherein the single crystalline substrate is a group 4 single crystalline substrate; a groups 3-5 single crystalline substrate; a groups 2-6 single crystalline substrate; a groups 4-6 single crystalline substrate; a sapphire single crystalline substrate; a silicon oxide single crystalline substrate; or a stacked substrate thereof.
